(19) United States
(12) Patent Application Publication
(10) Pub. No.: US 2025/0079792 A1
(43) Pub. Date: Mar. 6, 2025

(54) SEMICONDUCTOR LIGHT-EMITTING ELEMENT

(71) Applicant: HAMAMATSU PHOTONICS K.K., Hamamatsu-shi, Shizuoka (JP)

(72) Inventors: Kibo OTE, Hamamatsu-shi, Shizuoka (JP); Yoshitaka KUROSAKA, Hamamatsu-shi, Shizuoka (JP); Kazuyoshi HIROSE, Hamamatsu-shi, Shizuoka (JP); Yuu TAKIGUCHI, Hamamatsu-shi, Shizuoka (JP); Takahiro SUGIYAMA, Hamamatsu-shi, Shizuoka (JP); Soh UENOYAMA, Hamamatsu-shi, Shizuoka (JP)

(73) Assignee: HAMAMATSU PHOTONICS K.K., Hamamatsu-shi, Shizuoka (JP)

(21) Appl. No.: 18/844,129

(22) PCT Filed: Mar. 6, 2023
(86) PCT No.: PCT/JP2023/008385

§ 371 Date: Sep. 5, 2024

(30) Foreign Application Priority Data
Mar. 9, 2022 (JP) 2022-036004

(51) Int. Cl. H01S 5/042; H01S 5/22; H01S 5/223

(52) U.S. Cl. CPC H01S 5/04256; H01S 5/222; H01S 5/2231

(57) ABSTRACT

A semiconductor light-emitting element includes a semiconductor stacked layer, an electrode, and an electrode. The semiconductor stacked layer includes an active layer and a phase modulation layer. The phase modulation layer includes a plurality of phase modulation areas. Each of the plurality of phase modulation areas includes a basic region which has a first refractive index and a plurality of different-refractive-index regions which have a second refractive index different from the first refractive index and which are distributed in a two-dimensional shape. The electrode includes a plurality of electrode parts overlapping the plurality of phase modulation areas when seen in a stacking direction of the semiconductor stacked layer. The plurality of electrode parts are electrically isolated from each other. Laser light oscillating in each of the plurality of phase modulation areas is applied to a common irradiation area as light images according to arrangement of the plurality of different-refractive-index regions.

### TECHNICAL FIELD

The present disclosure relates to a semiconductor light-emitting element.

### BACKGROUND ART

Patent Literature 1 discloses a technique associated with a light emitting element. The light emitting element is a static-integrable phase modulating (S-iPM) laser and outputs light for forming a light image in at least one of a normal direction of a main surface and an oblique direction oblique with respect to the normal direction. The light emitting element includes a substrate including the main surface, a light emitting unit provided on the substrate, and a phase modulation layer. The phase modulation layer is provided on the substrate in a state in which the phase modulation layer is optically coupled to the light emitting unit and includes a basic layer with a predetermined refractive index and a plurality of different-refractive-index regions with a refractive index different from the refractive index of the basic layer. On a designed plane of the phase modulation layer perpendicular to the normal direction, each of the plurality of the different-refractive-index regions is disposed to correspond to a lattice point of a virtual tetragonal lattice in a one-to-one manner. At a plurality of effective lattice points correlated with the plurality of the different-refractive-index regions out of lattice points constituting the virtual tetragonal lattice, a line segment connecting an arbitrary specific lattice point and the centroid of a specific different-refractive-index region correlated with the specific lattice point is parallel to line segments connecting a plurality of neighboring lattice points adjacent to the specific lattice point at a shortest distance and the centroids of a plurality of different-refractive-index regions correlated with the plurality of neighboring lattice points.

### CITATION LIST

### Patent Literature

[Patent Literature 1] PCT International Publication No. WO2019/111787

### Non-Patent Literature

[Non-Patent Literature 1]Y. Kurosaka et al., “Effects of non-lasing band in two-dimensional photonic-crystal lasers clarified using omnidirectional band structure,” Opt. Express 20, 21773-21783 (2012)

### SUMMARY OF INVENTION

### Technical Problem

Semiconductor light-emitting elements for outputting an arbitrary light image by controlling a phase spectrum and an intensity spectrum of light which are output from a plurality of light emitting points distributed in a two-dimensional shape have been studied. A structure including a phase modulation layer provided on a substrate is known as one structure of such a semiconductor light-emitting element. The phase modulation layer includes a basic layer and a plurality of different-refractive-index regions with a refractive index which is different from a refractive index of the basic layer. When a virtual tetragonal lattice is set on a plane perpendicular to a thickness direction of the phase modulation layer, the different-refractive-index regions are arranged such that each position of the centroids departs from a position of the corresponding lattice point of the virtual tetragonal lattice according to a light image to be output. The semiconductor light-emitting element is called an S-iPM laser and outputs light for forming a light image of an arbitrary shape in a direction oblique to the normal direction of the main surface of the substrate.

In the related art, a semiconductor light-emitting element in which a plurality of different-refractive-index regions are arranged in advance according to a predetermined light image in the phase modulation layer like the light emitting element described in Patent Literature 1 is known as such a semiconductor light-emitting element. Since the plurality of regions with a different refractive index are formed in the phase modulation layer in advance, the positions of the regions with a different refractive index are fixed. Accordingly, a light image output from the semiconductor light-emitting element is static, and the light image is not movable. However, when the light image to be output can change dynamically, an application range of the semiconductor light-emitting element for outputting an arbitrary light image is likely to be widened. The present disclosure provides a semiconductor light-emitting element that can dynamically change a light image to be output.

### Solution to Problem

A semiconductor light-emitting element according to the present disclosure includes a semiconductor stacked layer, a first electrode, and a second electrode. The semiconductor stacked layer has a stacked structure including an active layer and a phase modulation layer between a first face and a second face. The phase modulation layer includes a plurality of phase modulation areas which are arranged on a virtual plane perpendicular to a thickness direction of the phase modulation layer and which are optically coupled to each other. Each of the plurality of phase modulation areas includes a basic region with a first refractive index and a plurality of different-refractive-index regions. The plurality of different-refractive-index regions are provided in the basic region, have a second refractive index different from the first refractive index, and are distributed in a two-dimensional shape along the virtual plane. The first electrode is opposite to the first face of the semiconductor stacked layer. The second electrode is opposite to the second face of the semiconductor stacked layer. One or both of the first electrode and the second electrode include a plurality of electrode parts overlapping the plurality of phase modulation areas respectively when seen in a stacking direction of the semiconductor stacked layer. The plurality of electrode parts are electrically isolated from each other. Light output from the active layer oscillates along the virtual plane in each of the plurality of phase modulation areas of the phase modulation layer and is applied from the plurality of phase modulation areas to a common irradiation area as light images according to arrangement of the plurality of different-refractive-index regions. The common irradiation area is located in a direction crossing both of the first face and the second face of the semiconductor stacked layer. The light images output from the plurality of phase modulation areas are synchronized in phase with each other.

In the semiconductor light-emitting element, one or both of the first electrode and the second electrode include a plurality of electrode parts overlapping a plurality of phase modulation areas. The plurality of electrode parts are electrically isolated from each other. Accordingly, independent currents can be supplied to the plurality of electrode parts. As a result, it is possible to independently control light emission intensities of a plurality of areas of the active layer for supplying light to the plurality of phase modulation areas and to independently control light intensities of the plurality of light images output from the plurality of phase modulation areas. The plurality of light images are applied to a common irradiation area. At this time, since the light images output from the plurality of phase modulation areas are synchronized in phase with each other, the plurality of light images can interfere with each other in the common irradiation area. In this way, according to the semiconductor light-emitting element, it is possible to form one light image by causing the plurality of light images to interfere with each other while individually adjusting the light intensities of the plurality of light images output from the plurality of phase modulation areas. Accordingly, it is possible to dynamically change a light image.

In the semiconductor light-emitting element, a light intensity distribution of the light image output from each of the plurality of phase modulation areas may include a sinusoidal distribution in which a period or phase in at least one direction differs for each phase modulation area in at least two phase modulation areas of the plurality of phase modulation areas. Alternatively, in the semiconductor light-emitting element, a light intensity distribution of the light image output from each of the plurality of phase modulation areas may include a sinusoidal distribution in which a period or phase in two directions perpendicular to each other differs for each phase modulation area in at least two phase modulation areas of the plurality of phase modulation areas. In these cases, it is possible to obtain an arbitrary light image by superimposing the plurality of light images output from the plurality of phase modulation areas on each other while individually adjusting the light intensities of the plurality of light images. Particularly, when the period of the sinusoidal distribution differs for each phase modulation area, the plurality of light images output from the plurality of phase modulation areas can serve as a plurality of base images in a discrete cosine transform (DCT).

In the semiconductor light-emitting element, a virtual tetragonal lattice along the virtual plane is set and a straight line passing through a corresponding lattice point and being oblique by the same angle with respect to the tetragonal lattice is set for each of a plurality of lattice points of the tetragonal lattice. At that time, the centroid of each of the plurality of different-refractive-index regions may be disposed on the corresponding straight line in each of the plurality of phase modulation areas, and a distance between the centroid of each of the plurality of different-refractive-index regions and the corresponding lattice point of each of the plurality of different-refractive-index regions may be individually set according to a predetermined light image as the light image. For example, with this configuration, the plurality of parts of the semiconductor light-emitting element including a phase modulation area can constitute S-iPM lasers and output predetermined light images different from each other. It is also possible to make polarization directions same among the plurality of phase modulation areas.

In the semiconductor light-emitting element, the phase modulation layer may further include a connection area located between neighboring phase modulation areas out of the plurality of phase modulation areas. The connection area may include a basic region with the first refractive index and a plurality of different-refractive-index regions with the second refractive index, and the centroids of the plurality of different-refractive-index regions of the connection area may be located at the lattice points of the tetragonal lattice. In this case, since a gap is provided between neighboring phase modulation areas, it is possible to widen gaps between a plurality of electrode parts. Accordingly, it is possible to reduce so-called inter-area crosstalk in which a part of currents to be supplied to the areas of the active layer for supplying light to the phase modulation areas leak to neighboring areas. Since the centroids of the plurality of different-refractive-index regions of the connection area are located at the lattice points of the tetragonal lattices, it is possible to synchronize phases of the light images output from the plurality of phase modulation areas with each other.

In the semiconductor light-emitting element, a planar shape of the connection area when seen in a stacking direction of the semiconductor stacked layer may be a lattice shape. In this case, since a gap can be provided between all the phase modulation areas, it is possible to more effectively reduce the inter-area crosstalk.

In the semiconductor light-emitting element, areas of the plurality of different-refractive-index regions on a section perpendicular to a thickness direction of the phase modulation layer may be individually set according to a predetermined light image as the light image. In this case, since a light intensity in addition to a phase can be adjusted for each different-refractive-index region, it is possible to enhance a degree of freedom in design of light images.

In the semiconductor light-emitting element, the tetragonal lattices of the neighboring phase modulation areas out of the plurality of phase modulation areas may be offset from each other.

The semiconductor light-emitting element may further include a λ/4 plate provided to face a light emission surface of the semiconductor light-emitting element, and the tetragonal lattices of the neighboring phase modulation areas out of the plurality of phase modulation areas may be offset from each other by n·a+a/2 (where a is a lattice spacing, and n is an integer equal to or greater than 0). In this case, phases of light images output from neighboring phase modulation areas are offset from each other by π (rad). Accordingly, it is possible to output circularly polarized light in the opposite directions from neighboring phase modulation areas.

In the semiconductor light-emitting element, the first electrode may include a plurality of electrode parts, the stacked structure may further include a clad layer provided between a layer group including the phase modulation layer and the active layer and the first face, and the clad layer may include a high-resistance region located between the neighboring phase modulation areas out of the plurality of phase modulation areas when seen in a stacking direction of the semiconductor stacked layer. In this case, it is possible to reduce the inter-area crosstalk.

In the semiconductor light-emitting element, the phase modulation layer may be provided between the clad layer and the active layer, and the high-resistance region may extend from a boundary of the clad layer on the first face side to the phase modulation layer. In this case, it is possible to more effectively reduce the inter-area crosstalk.

In the semiconductor light-emitting element, a planar shape of the high-resistance region when seen in the stacking direction of the semiconductor stacked layer may be a lattice shape. In this case, the high-resistance region can be provided between all the phase modulation areas when seen in the stacking direction. Accordingly, it is possible to more effectively reduce the inter-area crosstalk.

The semiconductor light-emitting element may further include a semiconductor substrate including a main surface and a rear surface. The semiconductor stacked layer may be provided on the main surface of the semiconductor substrate, and the second face of the semiconductor stacked layer may be opposite to the main surface of the semiconductor substrate. The first electrode may be provided on the first face and includes the plurality of electrode parts, and the second electrode may be provided on the rear surface of the semiconductor substrate. In this way, since the plurality of electrode parts are provided on the surface opposite to the semiconductor substrate with respect to the semiconductor stacked layer, it is possible to decrease distances between the plurality of electrode parts and the active layer. Accordingly, it is possible to reduce the inter-area crosstalk.

### Advantageous Effects of Invention

According to the present disclosure, it is possible to provide a semiconductor light-emitting element that can dynamically change a light image to be output.

### BRIEF DESCRIPTION OF DRAWINGS

FIG. 1 is a sectional view illustrating a stacked structure of a semiconductor light-emitting element to which a phase distribution design method according to an embodiment is applied.

FIG. 2 is a plan view of a phase modulation layer (when seen in a thickness direction thereof).

FIG. 3 is an enlarged plan view of a part of a phase modulation area.

FIG. 4 is an enlarged view of a single unit constituent area.

FIG. 5 is a diagram illustrating coordinate transformation from spherical coordinates to coordinates in an XYZ orthogonal coordinate system.

FIG. 6 is a partially enlarged plan view of a connection area.

FIG. 7 is a diagram schematically illustrating planar shapes of a first electrode and a second electrode and a configuration for supplying a current to the first electrode and the second electrode.

FIG. 8 is a diagram illustrating an electromagnetic field distribution in phase modulation areas, where Part (a) illustrates an electromagnetic field distribution in a resonance mode with symmetry A₁ at M₁ points and Part (b) illustrates an electromagnetic field distribution in a resonance mode with symmetry B₂ at M₁ points.

FIG. 9 is a diagram illustrating an electromagnetic field distribution according to a comparative example, where Part (a) illustrates an electromagnetic field distribution in a resonance mode with symmetry A₁ at M₁ points and Part (b) illustrates an electromagnetic field distribution in a resonance mode with symmetry B₂ at M₁ points.

FIG. 10 is a diagram conceptually illustrating an example of a plurality of light images output from a plurality of phase modulation areas.

FIG. 11 is a diagram conceptually illustrating another example of a plurality of light images output from a plurality of phase modulation areas.

FIG. 12 is a diagram conceptually illustrating another example of a plurality of light images output from a plurality of phase modulation areas.

FIG. 13 is a diagram conceptually illustrating a first design method.

FIG. 14 is a diagram illustrating a phase modulation layer including a total of four phase modulation areas of two columns in an X direction and two rows in a Y direction.

FIG. 15 is a diagram illustrating a phase modulation layer in which two phase modulation areas included in a first row have phase distribution pattern B and two phase modulation areas included in a second row have phase distribution pattern A.

FIG. 16 is a diagram conceptually illustrating a design method of phase distribution patterns A and B.

FIG. 17 is a diagram illustrating a phase modulation layer including a total of m×n phase modulation areas of m columns in the X direction and n rows in the Y direction.

FIG. 18 is a diagram conceptually illustrating a method of designing m×n phase distribution patterns.

FIG. 19 is a diagram conceptually illustrating a second design method.

FIG. 20 is a diagram conceptually illustrating a design method of phase distribution patterns A and B.

FIG. 21 is a diagram conceptually illustrating a method of designing m×n phase distribution patterns.

FIG. 22 is a sectional view illustrating a stacked structure of a semiconductor light-emitting element according to a first modified example.

FIG. 23 is a plan view of a clad layer.

FIG. 24 is a sectional view illustrating a configuration of a semiconductor light-emitting element according to a second modified example.

FIG. 25 is a plan view of a phase modulation layer.

FIG. 26 is a partially enlarged plan view of a phase shift area and a connection area near the phase shift area.

FIG. 27 is an enlarged view of a single unit constituent area.

Part (a) of FIG. 28 is a diagram illustrating a desired light image in an irradiation area (a far field) which is set when phase distribution pattern A is designed, Part (b) of FIG. 28 is a diagram illustrating a light image obtained by converting the light image illustrated in Part (a) to a wave number space, that is, a target amplitude distribution in the wave number space, and Part (c) of FIG. 28 is a diagram illustrating phase distribution pattern A which is calculated on the basis of the target amplitude distribution illustrated in Part (b).

Part (a) of FIG. 29 is a diagram illustrating a desired light image in an irradiation area (a far field) which is set when phase distribution pattern B is designed, Part (b) of FIG. 29 is a diagram illustrating a light image obtained by converting the light image illustrated in Part (a) to a wave number space, that is, a target amplitude distribution in the wave number space, and Part (c) of FIG. 29 is a diagram illustrating phase distribution pattern B which is calculated on the basis of the target amplitude distribution illustrated in Part (b).

Part (a) of FIG. 30 is a diagram illustrating an example in which phase distribution pattern A is applied to two phase modulation areas located on one diagonal and phase distribution pattern B is applied to two phase modulation areas located on the other diagonal, and Part (b) of FIG. 30 is a diagram conceptually illustrating a difference between a light intensity of two phase modulation areas located on one diagonal and a light intensity of two phase modulation areas located on the other diagonal which is realized by individually controlling currents of electrode parts.

FIG. 31 is a diagram illustrating a final light image which is supposed when light images output from two phase modulation areas with phase distribution pattern A and light images output from two phase modulation areas with phase distribution pattern B are caused to interfere with each other.

Part (a) of FIG. 32 illustrates a final light image obtained using the first design method, and Part (b) of FIG. 32 illustrates a final light image obtained using the second design method.

Part (a) of FIG. 33 is a diagram illustrating a desired light image in an irradiation area (a far field) which is set when phase distribution pattern A is designed, Part (b) of FIG. 33 is a diagram illustrating a light image obtained by converting the light image illustrated in Part (a) to a wave number space, that is, a target amplitude distribution in the wave number space, and Part (c) of FIG. 33 is a diagram illustrating phase distribution pattern A which is calculated on the basis of the target amplitude distribution illustrated in Part (b).

Part (a) of FIG. 34 is a diagram illustrating a desired light image in an irradiation area (a far field) which is set when phase distribution pattern B is designed, Part (b) of FIG. 34 is a diagram illustrating a light image obtained by converting the light image illustrated in Part (a) to a wave number space, that is, a target amplitude distribution in the wave number space, and Part (c) of FIG. 34 is a diagram illustrating phase distribution pattern B which is calculated on the basis of the target amplitude distribution illustrated in Part (b).

Part (a) of FIG. 35 is a diagram illustrating an example in which phase distribution pattern A is applied to two phase modulation areas located on one diagonal and phase distribution pattern B is applied to two phase modulation areas located on the other diagonal, and Part (b) of FIG. 35 is a diagram conceptually illustrating a difference between a light intensity of two phase modulation areas located on one diagonal and a light intensity of two phase modulation areas located on the other diagonal which is realized by individually controlling currents of electrode parts.

FIG. 36 is a diagram illustrating a final light image which is supposed when light images output from a phase modulation area with phase distribution pattern A and light images output from a phase modulation area with phase distribution pattern B are caused to interfere with each other.

FIG. 37 is a diagram illustrating a final light image obtained by simulation.

FIG. 38 is a diagram illustrating a final light image obtained by simulation.

### DESCRIPTION OF EMBODIMENTS

Specific examples of a semiconductor light-emitting element according to the present disclosure will be described below with reference to the accompanying drawings. The present disclosure is not limited to such examples and is intended to be represented by the appended claims and to include all modifications with meanings and scopes equivalent to the claims. In the following description, the same elements in description with reference to the drawings will be referred to by the same reference signs, and description thereof will be omitted.

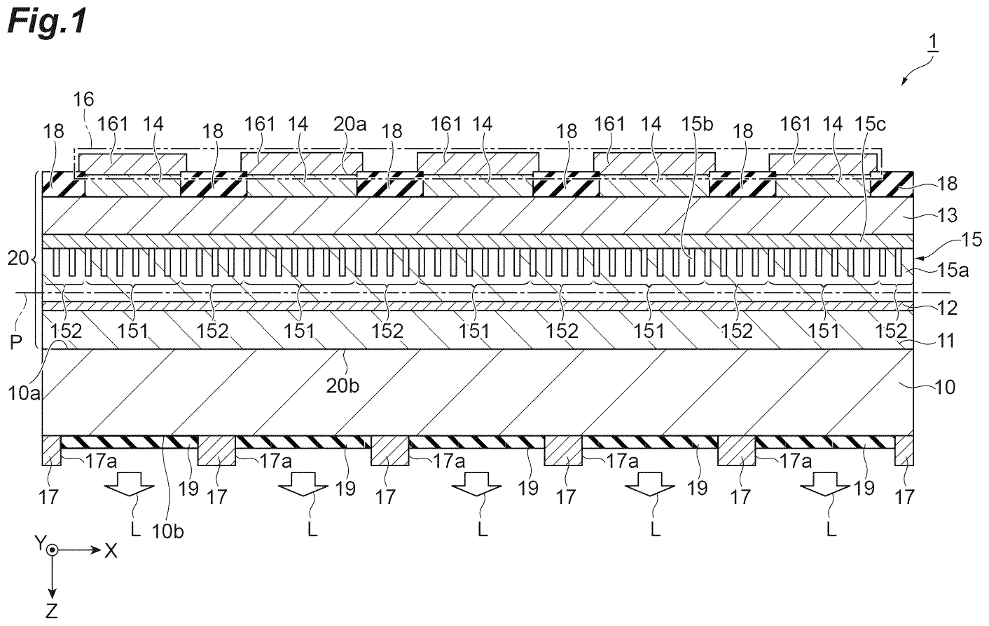

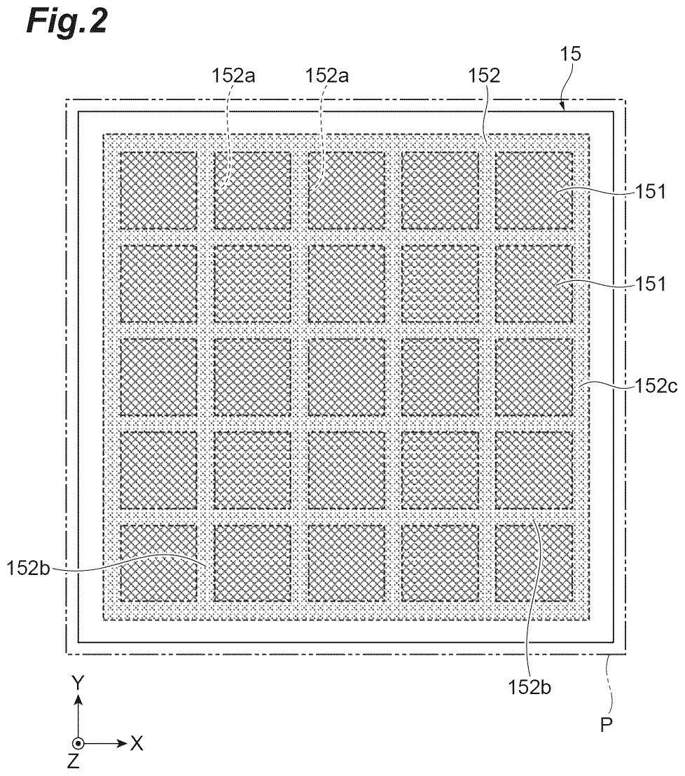

FIG. 1 is a sectional view illustrating a stacked structure of a semiconductor light-emitting element 1 to which a phase distribution design method according to an embodiment is applied. In FIG. 1, an XYZ orthogonal coordinate system with an axis extending in a thickness direction of the semiconductor light-emitting element 1 as a Z axis is defined. The semiconductor light-emitting element 1 is a laser light source that forms a standing wave in the XY plane direction and outputs a planar wave of which a phase has been controlled in a direction crossing the thickness direction. The semiconductor light-emitting element 1 is an S-iPM laser and can output an arbitrary-shaped light image in a direction perpendicular to a main surface 10a of a semiconductor substrate 10, that is, in the Z direction, a direction oblique to the Z direction, or a direction including both thereof.

The semiconductor light-emitting element 1 includes a semiconductor substrate 10. The semiconductor substrate 10 includes a main surface 10a and a rear surface 10b. A normal direction of the main surface 10a and the rear surface 10b and the thickness direction of the semiconductor substrate 10 are along the Z direction. The semiconductor substrate 10 is formed of, for example, a compound semiconductor such as a GaAs-based semiconductor, an InP-based semiconductor, or a nitride-based semiconductor.

The semiconductor light-emitting element 1 further includes a semiconductor stacked layer 20. The semiconductor stacked layer 20 is provided on the main surface 10a of the semiconductor substrate 10. A stacking direction of the semiconductor stacked layer 20 is along the Z direction. The semiconductor stacked layer 20 has a stacked structure in which a clad layer 11, an active layer 12, a clad layer 13, a contact layer 14, and a phase modulation layer 15 are included between a first face 20a and a second face 20b. The second face 20b of the semiconductor stacked layer 20 is opposite to the main surface 10a of the semiconductor substrate 10. In the illustrated example, the clad layer 11 is provided on the main surface 10a of the semiconductor substrate 10, the active layer 12 is provided on the clad layer 11, the phase modulation layer 15 is provided on the active layer 12, the clad layer 13 is provided on the phase modulation layer 15, and the contact layer 14 is provided on the clad layer 13. That is, the clad layer 11 is provided between the active layer 12 and the second face 20b, and the clad layer 13 is provided between the active layer 12 and the first face 20a, and the clad layers 11 and 13 have the active layer 12 and the phase modulation layer 15 interposed therebetween. In the illustrated example, the phase modulation layer 15 is provided between the active layer 12 and the clad layer 13, but the phase modulation layer 15 may be provided between the clad layer 11 and the active layer 12. A light guide layer may be provided in one or both of a layer between the active layer 12 and the clad layer 13 and a layer between the active layer 12 and the clad layer 11 according to necessity. The light guide layer may include a carrier barrier layer for efficiently confining carriers in the active layer 12.

The clad layer 11, the active layer 12, the clad layer 13, and the contact layer 14 are formed of, for example, a compound semiconductor such as a GaAs-based semiconductor, an InP-based semiconductor, or a nitride-based semiconductor. The active layer 12 has, for example, a multi-quantum well structure. An energy bandgap of the clad layer 11 and an energy bandgap of the clad layer 13 are larger than an energy bandgap of the active layer 12. The thickness directions of the clad layer 11, the active layer 12, the clad layer 13, and the contact layer 14 are coincide with the Z-axis direction.

The phase modulation layer 15 is optically coupled to the active layer 12. The thickness direction of the phase modulation layer 15 is coincides with the Z-axis direction. FIG. 2 is a plan view of the phase modulation layer 15 (a view in the thickness direction). As illustrated in FIGS. 1 and 2, the phase modulation layer 15 includes a plurality of phase modulation areas 151 and a connection area 152. A planar shape of the connection area 152 when seen in the stacking direction of the semiconductor stacked layer 20 is, for example, a lattice shape. The plurality of phase modulation areas 151 are provided at a plurality of openings 152a of the connection area 152 formed in the lattice shape.

A planar shape of each of the plurality of phase modulation areas 151 is, for example, square or rectangular. The plurality of phase modulation areas 151 are two-dimensionally arranged on a virtual plane P perpendicular to the thickness direction of the phase modulation layer 15 (that is, parallel to the XY plane) and are optically coupled to each other. In the illustrated example, the plurality of phase modulation areas 151 are arranged in the X direction and the Y direction. In the illustrated example, the plurality of phase modulation areas 151 are two-dimensionally arranged, but the plurality of phase modulation areas 151 may be one-dimensionally arranged. In the illustrated example, the plurality of phase modulation areas 151 are arranged with intervals therebetween. The connection area 152 includes a part 152b provided between the neighboring phase modulation areas 151 and a frame-shaped part 152c surrounding the plurality of phase modulation areas 151 together.

As illustrated in FIG. 1, each of the plurality of phase modulation areas 151 includes a basic region 15a and a plurality of different-refractive-index regions 15b. Similarly, the connection area 152 also includes a basic region 15a and a plurality of different-refractive-index regions 15b. The basic region 15a is formed of a first refractive-index medium. The basic region 15a is formed of, for example, a compound semiconductor such as a GaAs-based semiconductor, an InP-based semiconductor, or a nitride-based semiconductor. The plurality of different-refractive-index regions 15b are formed of a second refractive-index medium of which the refractive index is different from that of the first refractive-index medium and are present in the basic region 15a. The different-refractive-index regions 15b are, for example, voids. The different-refractive-index regions 15b are covered by a cap region 15c provided on the basic region 15a. The cap region 15c constitutes a part of the phase modulation layer 15 and is formed of, for example, the same material as the basic region 15a.

The plurality of different-refractive-index regions 15b are distributed in a two-dimensional shape on a virtual plane P. In each phase modulation area 151, the plurality of different-refractive-index regions 15b include a substantially periodical structure of a lattice shape. When an equivalent refractive index of a mode is n and a lattice spacing is a, a wavelength λ₀ selected by each phase modulation area 151 is expressed by λ₀=(√2)a×n, for example, in a case of M₁-point oscillation. This wavelength λ₀ is included in an emission wavelength range of the active layer 12. Each phase modulation area 151 selects a band end wavelength near the wavelength λ₀ out of emission wavelengths of the active layer 12 and outputs the selected band end wavelength to the outside. Light incident on each phase modulation area 151 from the active layer 12 forms a predetermined mode based on the arrangement of the different-refractive-index regions 15b in each phase modulation area 151 and is output as laser light L from the rear surface 10b of the semiconductor substrate 10 to the outside of the semiconductor light-emitting element 1.

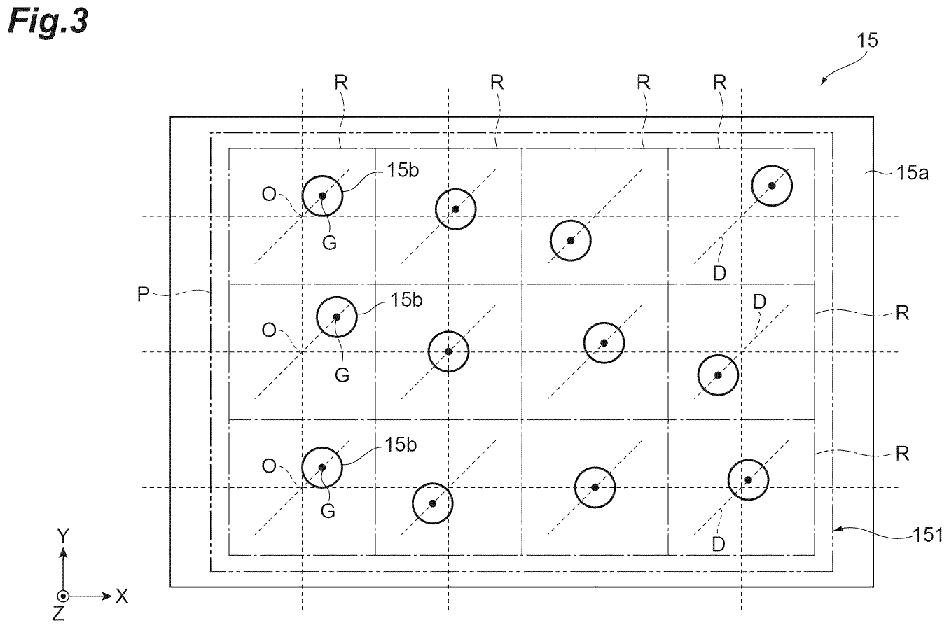

FIG. 3 is an enlarged plan view of a part of the phase modulation area 151. Only one phase modulation area 151 is illustrated in FIG. 3, and the other phase modulation areas 151 have the same configuration. As described above, each phase modulation area 151 includes the basic region 15a and the plurality of different-refractive-index regions 15b. In FIG. 3, virtual tetragonal lattices on the virtual plane P are set for the phase modulation area 151. One side of each tetragonal lattice is parallel to the X axis, and the other side is parallel to the Y axis. Unit constituent areas R with a square shape centered on lattice points O of the tetragonal lattice are two-dimensionally arranged in a plurality of columns along the X axis and a plurality of rows along the Y axis. XY coordinates of each unit constituent area R are defined by a position of the centroid of the corresponding unit constituent area R. The positions of the centroids match the lattice points O of the virtual tetragonal lattice. For example, one different-refractive-index region 15b is provided in each unit constituent area R. A planar shape of the different-refractive-index region 15b is, for example, circular. The lattice point O may be located outside of the different-refractive-index region 15b or may be located inside of the different-refractive-index region 15b.

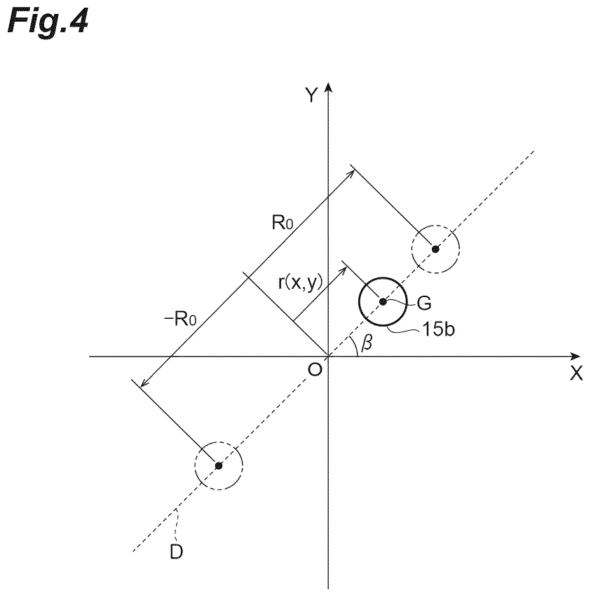

FIG. 4 is an enlarged view of one unit constituent area R. As illustrated in the drawing, each different-refractive-index region 15b has the centroid G. The centroid G of the different-refractive-index region 15b is disposed on a straight line D which is set for each lattice point O. The straight line D is a straight line which passes through the lattice point O corresponding to the corresponding unit constituent area R and which is oblique to the sides of the tetragonal lattice. That is, the straight line D is a straight line which is oblique to both the X axis and the Y axis. A tilt angle of the straight line D with respect to one side of the tetragonal lattice, that is, the X axis, is β.

The tilt angle β is the same for all the straight lines D in the phase modulation area 151. The tilt angle β is the same for all of the plurality of phase modulation areas 151. The tilt angle β satisfies 0°<β<90° and is, for example, β=45°. Alternatively, the tilt angle β satisfies 180°<β<270° and is, for example, β=225°. When the tilt angle β satisfies 0°<β<90° or 180°<β<270°, the straight line D extends from the first quadrant to the third quadrant of a coordinate plane which is defined by the X axis and the Y axis. The tilt angle β satisfies 90°<β<180° and is, for example, β=135°. Alternatively, the tilt angle β satisfies 270°<β<360° and is, for example, β=315°. When the tilt angle β satisfies 90°<β<180° or 270°<β<360°, the straight line D extends from the second quadrant to the fourth quadrant of the coordinate plane which is defined by the X axis and the Y axis. In this way, the tilt angle β is an angle other than 0°, 90°, 180°, and 270°.

Here, it is assumed that a distance between the lattice point O and the centroid G is r(x, y). Here, x is a position of an x-th lattice point on the X axis, and y is a position of a y-th lattice point on the Y axis. When the distance r(x, y) has a positive value, the centroid G is located in the first quadrant or the second quadrant. When the distance r(x, y) has a negative value, the centroid G is located in the third quadrant or the fourth quadrant. When the distance r(x, y) is 0, the lattice point O and the centroid G match each other. The tilt angle is preferably 45°, 135°, 225°, or 275°. With these tilt angles, only two out of four wave number vectors forming a standing wave at M points, for example, in-plane wave number vectors (±π/a, ±π/a), are modulated in phase, and the other two wave number vectors are not modulated in phase. Accordingly, it is possible to form a stable standing wave.

The distance r(x, y) is individually set for each different-refractive-index region 15b according to a phase distribution ϕ(x, y) corresponding to a light image to be output from each phase modulation area 151. That is, when a phase ϕ(x, y) at certain coordinates (x, y) is ϕ₀, the distance r(x, y) is set to 0. When the phase ϕ(x, y) is π+ϕ₀, the distance r(x, y) is set to a maximum value R₀. When the phase ϕ(x, y) is −π+ϕ₀, the distance r(x, y) is set to a minimum value −R₀. For an intermediate phase ϕ(x, y) therebetween, the distance r(x, y) is set to satisfy r(x, y)={ϕ(x, y)−ϕ₀}×R₀/π. When a lattice spacing of a virtual tetragonal lattice is defined as a, the maximum value R₀ of the distance r(x, y) falls within, for example, the range of Formula (1).

$$\begin{matrix}[ Formula 1 ] & \\ 0 \leq {R}_{0} \leq \frac{a}{\sqrt{2}} & ( 1 )\end{matrix}$$

The initial phase ϕ₀ can be arbitrarily set. The distribution of the phase ϕ(x, y) and the distribution of the distance r(x, y) have specific values for each position which is determined by the values of x and y, but cannot be said to be expressed by a specific function.

By determining the distribution of the distance r(x, y) of the different-refractive-index regions 15b of the plurality of phase modulation areas 151, it is possible to output a desired light image from each of the plurality of phase modulation areas 151. The phase modulation areas 151 are configured to satisfy the following conditions.

As a first precondition, a virtual tetragonal lattice including M₁×N₁ unit constituent areas R having a square shape is set on the XY plane. M₁ and N₁ are integers equal to or greater than 1.

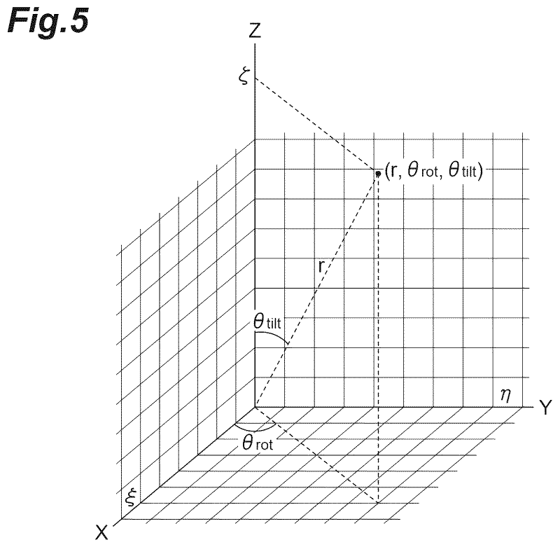

As illustrated in FIG. 5, spherical coordinates (r, θᵣₒₜ, θₜ, θₜᵢₗₜ) are defined by a length r of a radius vector, a tilt angle θₜᵢₗₜ from the Z axis, and a rotation angle θᵣₒₜ from the X axis which is identified on the XY plane. As a second precondition, it is assumed that coordinates (ξ, η, ζ) in the XYZ orthogonal coordinate system satisfy the relationships represented by Formulas (2) to (4) with respect to the spherical coordinates (r, θᵣₒₜ, θₜᵢₗₜ). FIG. 5 is a diagram illustrating coordinate transformation from the spherical coordinates (r, θᵣₒₜ, θₜᵢₗₜ) to coordinates (ξ, η, ζ) in the XYZ orthogonal coordinate system. A light image in design on a predetermined plane set in the XYZ orthogonal coordinate system which is a real space is represented by the coordinates (ξ, η, ζ).

$$\begin{matrix}[ Formula 2 ] & \\ ξ = r sin {θ}_{tilt} cos {θ}_{rot} & ( 2 )\end{matrix}$$

$$\begin{matrix}[ Formula 3 ] & \\ η = r sin {θ}_{tilt} sin {θ}_{rot} & ( 3 )\end{matrix}$$

$$\begin{matrix}[ Formula 4 ] & \\ ζ = r cos {θ}_{tilt} & ( 4 )\end{matrix}$$

Light emitted from each phase modulation area 151 is a set of bright spots in a direction which is defined by the angles θₜᵢₗₜ and θᵣₒₜ. In this case, the angles θₜᵢₗₜ and θᵣₒₜ are converted to coordinate values kx and ky. The coordinate value kx is a standardized wave number defined by Formula (5) and is a coordinate value on a Kₓ axis corresponding to the X axis. The coordinate value ky is a standardized wave number defined by Formula (6) and is a coordinate value on a K_{y} axis corresponding to the Y axis and perpendicular to the Kₓ axis. The standardized wave number is a wave number which is standardized with a wave number 2π/a corresponding to the lattice spacing of the virtual tetragonal lattice as 1.0. In this case, in the wave number space defined by the Kₓ axis and the K_{y} axis, a specific wave number range including a beam pattern corresponding to a light image includes M₂×N₂ image areas FR with a square shape. M₂ and N₂ are integers equal to or greater than 1. The integer M₂ does not need to be equal to the integer M₁. The integer N₂ does not need to be equal to the integer N₁. Formulas (5) and (6) are disclosed in, for example, Non Patent Literature 1.

$$\begin{matrix}[ Formula 5 ] & \\ {k}_{x} = \frac{a}{λ} sin {θ}_{tilt} cos {θ}_{rot} & ( 5 )\end{matrix}$$

$$\begin{matrix}[ Formula 6 ] & \\ {k}_{y} = \frac{a}{λ} sin {θ}_{tilt} sin {θ}_{rot} & ( 6 )\end{matrix}$$

a: a lattice constant of the virtual tetragonal lattice
λ: an emission wavelength of the semiconductor light-emitting element 1

In the wave number space, an image area FR(kx, ky) is identified by a coordinate component kx in the Kr-axis direction and a coordinate component ky in the K_{y}-axis direction. The coordinate component kx is an integer equal to or greater than 0 and equal to or less than M₂−1. The coordinate component ky is an integer equal to or greater than 0 and equal to or less than N₂−1. A unit constituent area R(x, y) on the XY plane is identified by a coordinate component x in the X-axis direction and a coordinate component y in the Y-axis direction. The coordinate component x is an integer equal to or greater than 0 and equal to or less than M₁−1. The coordinate component y is an integer equal to or greater than 0 and equal to or less than N₁−1. As a third precondition, a complex amplitude CA(x, y) which is obtained by performing a two-dimensional inverse discrete Fourier transform on the image area FR(kx, ky) to the unit constituent area R(x, y) is represented by Formula (7) with j as an imaginary unit. The complex amplitude CA(x, y) is defined by Formula (8), where an amplitude term is defined as A(x, y) and a phase term is defined as ϕ(x, y). As a fourth precondition, the unit constituent area R(x, y) is defined by an s axis and a t axis. The s axis and the t axis are parallel to the X axis and the Y axis, respectively, and are orthogonal at a lattice point O(x, y) which is the center of the unit constituent area R(x, y).

$$\begin{matrix}[ Formula 7 ] & \\ CA ( x , y ) = {\sum }_{{k}_{x} = 0}^{M 2 - 1} {\sum }_{{k}_{y} = 0}^{N 2 - 1} FR ( {k}_{x} , {k}_{y} ) exp [ j 2 π ( \frac{{k}_{x}}{M 2} x + \frac{{k}_{y}}{N 2} y ) ] & ( 7 )\end{matrix}$$

$$\begin{matrix}[ Formula 8 ] & \\ CA ( x , y ) = A ( x , y ) \times exp [ j ϕ ( x , y ) ] & ( 8 )\end{matrix}$$

In the first to fourth preconditions, the phase modulation areas 151 are configured to satisfy the following conditions. That is, the corresponding different-refractive-index region 15b is disposed in the unit constituent area R(x, y) such that a distance r(x, y) from the lattice point O(x, y) to the centroid G of the corresponding different-refractive-index region 15b satisfies the following relationship.

$$r ( x , y ) = C \times ( ϕ ( x , y ) - {ϕ}_{0} )$$

C: a proportion coefficient, for example, R₀/π
ϕ₀: an arbitrary coefficient, for example, 0

When it is intended to acquire a desired light image, the light image can be subjected to an inverse Fourier transform, and a distribution of the distance r(x, y) corresponding to the phase ϕ(x, y) of a complex amplitude thereof can be applied to the plurality of different-refractive-index regions 15b. The phase ϕ(x, y) and the distance r(x, y) may be proportional to each other.

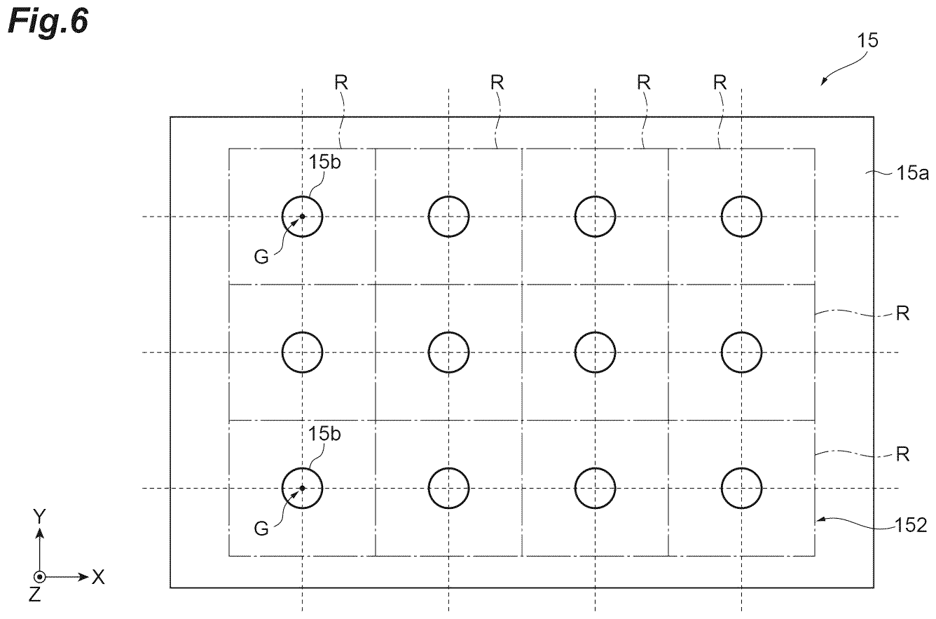

FIG. 6 is a partially enlarged plan view of the connection area 152. Only a part of the connection area 152 is illustrated in FIG. 6, and the configuration of the other parts of the connection area 152 is the same. As described above, the connection area 152 also includes a basic region 15a and a plurality of different-refractive-index regions 15b. In the connection area 152, the same virtual tetragonal lattice as in FIG. 3 is set. One side of the tetragonal lattice is parallel to the X axis, and the other side is parallel to the Y axis. The lattice constant a of the tetragonal lattice is the same as the lattice constant a of the tetragonal lattice of the phase modulation area 151. In the connection area 152, the centroids G of the plurality of different-refractive-index regions 15b are located at the lattice points of the tetragonal lattice. In other words, the positions of the centroids G of the plurality of different-refractive-index regions 15b match the positions of the lattice points of the tetragonal lattice. Accordingly, in the connection area 152, the plurality of different-refractive-index regions 15b are arranged periodically along the X axis and the Y axis.

Description will be continued with reference back to FIG. 1. The semiconductor light-emitting element 1 further includes an electrode 16 (a first electrode) and an electrode 17 (a second electrode). The electrode 16 is provided to face the first face 20a of the semiconductor stacked layer 20, and the electrode 16 is provided on the first face 20a, that is, the contact layer 14, in the illustrated example. The electrode 16 forms an ohmic contact with the contact layer 14. The electrode 17 is provided to face the second face 20b of the semiconductor stacked layer 20, and the electrode 17 is provided on the rear surface 10b of the semiconductor substrate 10 in the illustrated example. The electrode 17 forms an ohmic contact with the semiconductor substrate 10.

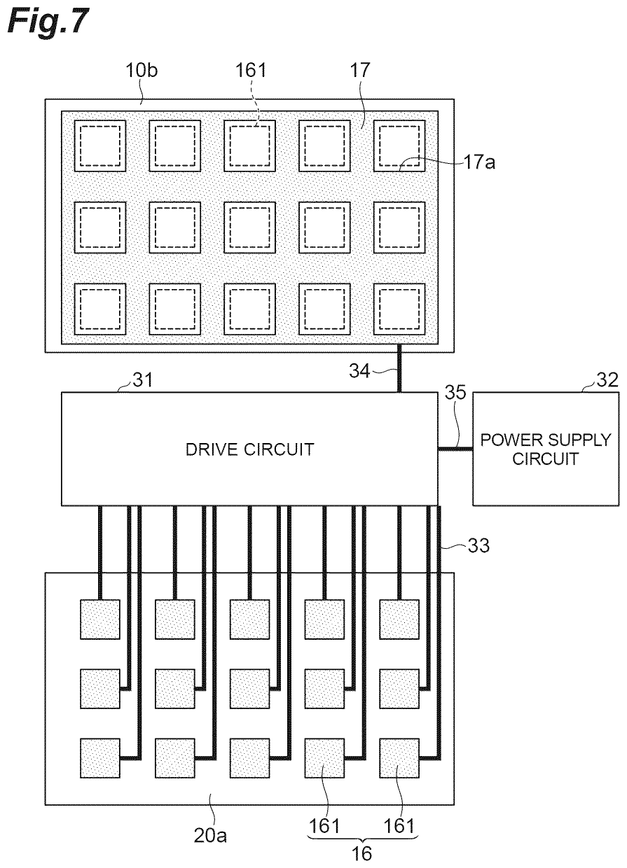

FIG. 7 is a diagram schematically illustrating planar shapes of the electrodes 16 and 17 and the configuration for supplying currents to the electrodes 16 and 17. As illustrated in FIG. 7, the electrode 17 includes a plurality of openings 17a. The openings 17a correspond to the phase modulation areas 151 in a one-to-one manner. When seen in the thickness direction of the semiconductor stacked layer 20, the openings 17a overlap the corresponding phase modulation areas 151. The planar shape of each opening 17a is, for example, a square shape or a rectangular shape. The electrode 16 includes a plurality of electrode parts 161. The plurality of electrode parts 161 are arranged with intervals therebetween and are electrically isolated from each other. When it is mentioned that the electrode parts are electrically isolated from each other, it means that there is no other electrical path except for a path passing through the semiconductor stacked layer 20. The electrode parts 161 correspond to the phase modulation areas 151 in a one-to-one manner. When seen in the thickness direction of the semiconductor stacked layer 20, the electrode parts 161 overlap the corresponding phase modulation areas 151. The planar shape of each electrode part 161 is, for example, a square shape or a rectangular shape.

The plurality of electrode parts 161 are individually electrically connected to a drive circuit 31 via a plurality of lines 33. The electrode 17 is electrically connected to the drive circuit 31 via a line 34. The drive circuit 31 is electrically connected to a power supply circuit 32 via a line 35. The drive circuit 31 is supplied with electric power from the power supply circuit 32 and supplies driving currents to the plurality of electrode parts 161 and the electrode 17. The drive circuit 31 can freely change the magnitude of the driving current for each electrode part 161. The magnitude of the driving current to the electrode parts 161 is independently set for each electrode part 161.

Description will be continued with reference back to FIG. 1. Parts other than parts of the contact layer 14 overlapping the electrode parts 161 are removed by etching in order to limit a current range. Accordingly, the contact layer 14 is divided to a plurality of parts respectively corresponding to the plurality of electrode parts 161. Gaps between the plurality of parts of the contact layer 14 are filled with a protection film 18. Accordingly, the surface of the semiconductor stacked layer 20 exposed from the electrode 16 is protected. The protection film 18 is formed of, for example, an inorganic insulator such as a silicon nitride (for example, SiN) or a silicon oxide (for example, SiO₂). Parts of the contact layer 14 other than the parts overlapping the electrode parts 161 may not be removed but be left. In this case, the protection film 18 is provided on the contact layer 14 of the gaps between the plurality of electrode parts 161.

On the rear surface 10b of the semiconductor substrate 10, an area that includes the insides of the openings 17a other than the area in which the electrode 17 is provided is covered with an antireflection film 19. The antireflection film 19 provided in an area other than the openings 17a may be removed. The antireflection film 19 is formed of, for example, a single-layered film or a multi-layered film of dielectrics such as a silicon nitride (for example, SiN) or a silicon oxide (for example, SiO₂). As the multi-layered film of a dielectric, for example, a film in which two or more types of dielectric layers selected from a dielectric layer group consisting of titanium oxide (TiO₂), silicon dioxide (SiO₂), silicon monoxide (SiO), niobium oxide (Nb₂O₅), tantalum pentoxide (Ta₂O₅), magnesium fluoride (MgF₂), titanium oxide (TiO₂), aluminum oxide (Al₂O₃), cerium oxide (CeO₂), indium oxide (In₂O₃), and zirconium oxide (ZrO₂) are stacked can be used. The multi-layered film of a dielectric is formed, for example, by stacking a plurality of films of which an optical thicknesses with respect to light of a wavelength λ is λ/4.

In this embodiment, the electrode 16 facing the first face 20a includes a plurality of electrode parts 161, but the electrode 17 facing the second face 20b may include a plurality of electrode parts instead of the configuration or in addition to the configuration. In this case, similarly to the plurality of electrode parts 161, the plurality of electrode parts of the electrode 17 are arranged with gaps therebetween and electrically isolated from each other. The electrode parts of the electrode 17 correspond to the phase modulation areas 151 in a one-to-one manner. When seen in the thickness direction of the semiconductor stacked layer 20, the electrode parts of the electrode 17 overlap the corresponding phase modulation areas 151. The planar shape of each electrode part of the electrode 17 is, for example, a rectangular frame shape including an opening 17a. The plurality of electrode parts of the electrode 17 are individually electrically connected to the drive circuit 31 via a plurality of lines. The drive circuit 31 freely changes the magnitude of a driving current for each electrode part of the electrode 17.

In the semiconductor light-emitting element 1, when a driving current is supplied between each electrode part 161 and the electrode 17, recombination of electrons and holes is caused in a part of the active layer 12 located just below the corresponding electrode part 161, and light is output from the corresponding part of the active layer 12. At this time, electrons and holes contributing to emission of light and light output from the active layer 12 are efficiently confined between the clad layer 11 and the clad layer 13.

Light output from the corresponding part of the active layer 12 is input into the phase modulation area 151 facing the part. Then, the light oscillates along the virtual plane P in the phase modulation area 151 and forms a predetermined mode based on the arrangement of the plurality of different-refractive-index regions 15b. Apart of laser light L output from the corresponding phase modulation area 151 is directly output to the outside of the semiconductor light-emitting element 1 from the rear surface 10b via the opening 17a. The remaining part of the laser light L output from the phase modulation area 151 is reflected by the electrode 16 and is then output to the outside of the semiconductor light-emitting element 1 from the rear surface 10b via the opening 17a. At this time, signal light included in the laser light L exits in a direction crossing both the first face 20a and the second face 20b of the semiconductor stacked layer 20. In other words, signal light included in the laser light L exits in an arbitrary direction including a direction perpendicular to the rear surface 10b and a direction oblique to the direction perpendicular to the rear surface 10b. Exit light from the semiconductor light-emitting element 1 includes signal light. The signal light is mainly one or both of 1st-order refracted light or −1st-order refracted light of the laser light. In the following description, 1st-order refracted light is referred to as 1st-order light, and −1st-order refracted light is referred to as −1st-order light.

Laser light L output from the plurality of phase modulation areas 151 is applied as light images based on the arrangement of the plurality of different-refractive-index regions 15b to a common irradiation area (a far field) which is located in a direction crossing both the first face 20a and the second face 20b of the semiconductor stacked layer 20. A plurality of different-refractive-index regions 15b included in at least two phase modulation areas 151 out of the plurality of phase modulation areas 151 have arrangements which are different for the phase modulation areas 151. Accordingly, a plurality of light images output from the plurality of phase modulation areas 151 interfere with each other to form a final light image.

In order to acquire a final light image by causing a plurality of light images output from the plurality of phase modulation areas 151 to interfere with each other, these light images are synchronized in phase with each other. In order to synchronize phases the phases of the light images with each other, in this embodiment, the connection area 152 is provided between neighboring phase modulation areas 151. Since the resonance modes in the neighboring phase modulation areas 151 are shared via the connection area 152, the phases of laser light L oscillating in the phase modulation areas 151 can be synchronized between the plurality of phase modulation areas 151. The connection area 152 may be removed to make the neighboring phase modulation areas 151 adjacent to each other. In this case, the phases of laser light L oscillating in the phase modulation areas 151 can be synchronized with each other between the plurality of phase modulation areas 151. In order to synchronize phases of a plurality of light images with each other, phase synchronization needs to be considered when the phase distribution ϕ(x, y) of the phase modulation areas 151 is designed. Design of the phase distribution ϕ(x, y) in consideration of phase synchronization will be described later.

In order to acquire a desired light image by causing the light images output from the plurality of phase modulation areas 151 to interfere with each other, it is preferable that polarization directions of the light images be aligned. In this embodiment, the centroids G of the different-refractive-index regions 15b are disposed on the straight line D set for the corresponding lattice points O. The tilt angles β of the straight lines D are the same at all the lattice points O in the phase modulation area 151 and are the same in the plurality of phase modulation areas 151.

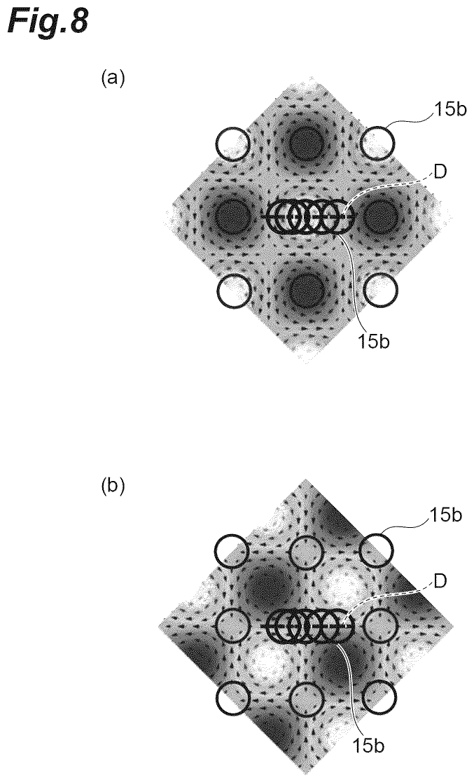

FIG. 8 is a diagram illustrating an electromagnetic field distribution in the phase modulation area 151. Part (a) of FIG. 8 illustrates an electromagnetic field distribution in a resonance mode with symmetry A₁ at M₁ points. Part (b) of FIG. 8 illustrates an electromagnetic field distribution in a resonance mode with symmetry B₂ at M₁ points. In FIG. 8, an arrow indicates a magnitude and a direction of an electric field, and color gradation indicates a magnitude of a magnetic field. In this embodiment, the centroid G of each different-refractive-index region 15b is disposed on the straight line D. In the drawing, a change in arrangement of the central different-refractive-index regions 15b is schematically illustrated. In this case, in any electromagnetic field distribution, the polarization directions are expected to be aligned regardless of the distance between the centroid G of the different-refractive-index region 15b and the lattice point O, that is, regardless of the phase values realized by the different-refractive-index regions 15b.

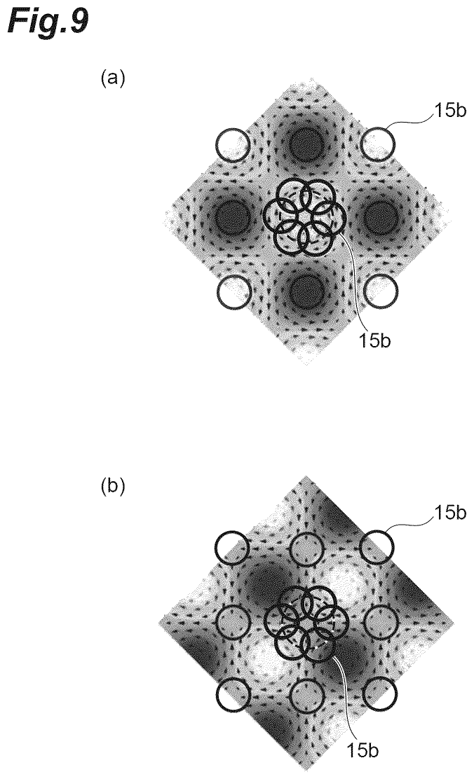

On the other hand, FIG. 9 is a diagram illustrating an electromagnetic field distribution according to a comparative example. In this example, the centroids G of the different-refractive-index regions 15b are disposed at a constant distance from the lattice point O, and an azimuth angle (a rotation angle) of a vector connecting the lattice point O to the centroid G about the lattice point O is set for each different-refractive-index region 15b according to the phase distribution ϕ(x, y). Part (a) of FIG. 9 illustrates an electromagnetic field distribution in the resonance mode with symmetry A₁ at M₁ points. Part (b) of FIG. 9 illustrates an electromagnetic field distribution in the resonance mode with symmetry B₂ at M₁ points. In FIG. 9, an arrow indicates a magnitude and a direction of an electric field, and color gradation indicates a magnitude of a magnetic field. In this comparative example, in any electromagnetic field distribution, the polarization direction changes according to the rotation angle of the different-refractive-index region 15b around the lattice point O. Accordingly, it cannot be expected that the polarization directions are aligned. In this regard, it is preferable that the centroid G of the different-refractive-index regions 15b be disposed on the straight line D and the distance between the centroid G and the lattice point O change according to the phase as in this embodiment.

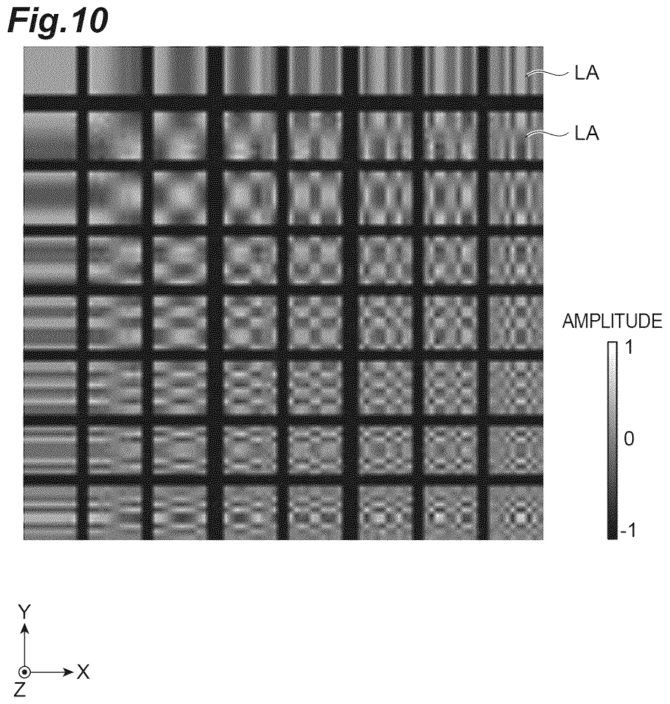

As described above, the semiconductor light-emitting element 1 according to this embodiment irradiates a common irradiation area with a plurality of light images output from the plurality of phase modulation areas 151. A final one light image (a hologram) is formed by causing the plurality of light images to overlap and interfere with each other. FIG. 10 is a diagram conceptually illustrating an example of a plurality of light images output from the plurality of phase modulation areas 151. In FIG. 10, a total of 64 light images LA of 8 columns in the X direction and 8 rows in the Y direction become darker as the light intensity thereof becomes smaller and become lighter as the light intensity thereof becomes larger. These are light images output from a total of 64 phase modulation areas 151 of 8 columns in the X direction and 8 rows in the Y direction. In this example, a light intensity distribution of the light images LA output from the plurality of phase modulation areas 151 includes a sinusoidal distribution. In the sinusoidal distribution, periods in two directions perpendicular to each other (the X direction and the Y direction) differ for each phase modulation area 151. These light images LA can be used, for example, as base images of a discrete cosine transform (DCT). That is, by converting a light intensity distribution of a target final light image using the discrete cosine transform and outputting the plurality of acquired base images from the plurality of phase modulation areas 151, the final light image can be realized. By changing the magnitude of the driving current of the plurality of electrode parts 161 corresponding to the plurality of phase modulation areas 151, it is also possible to individually adjust degrees of contribution of the base images to the final light image and to present a dynamic light image varying with time.

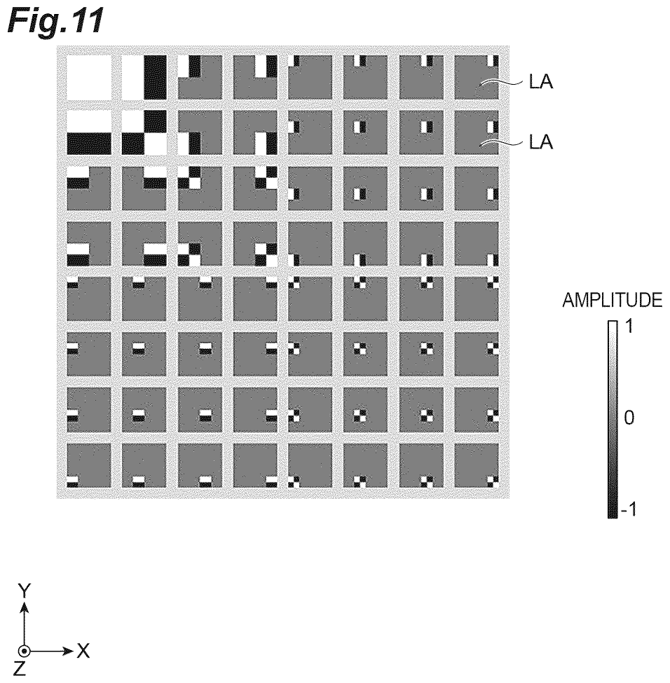

FIG. 11 is a diagram conceptually illustrating another example of the plurality of light images output from the plurality of phase modulation areas 151. This example employs a plurality of light images LA which are used as base images of a discrete wavelet transform (DWT). Like this example, by converting a light intensity distribution of a target final light image using the discrete wavelet transform and outputting the plurality of acquired base images from the plurality of phase modulation areas 151, the final light image can also be realized. By changing the magnitude of the driving current of the plurality of electrode parts 161 corresponding to the plurality of phase modulation areas 151, it is also possible to individually adjust degrees of contribution of the base images to the final light image and to present a dynamic light image varying with time.

As well as the discrete cosine transform and the discrete wavelet transform, the base images may be learned, for example, from a group of a plurality of light images to be displayed in a far field through machine learning (such as main component analysis or dictionary learning). In the example illustrated in FIG. 10, the periods in two directions perpendicular to each other (the X direction and the Y direction) differ for each phase modulation area 151, but the period in only one direction (the X direction or the Y direction) may differ for each phase modulation area 151.

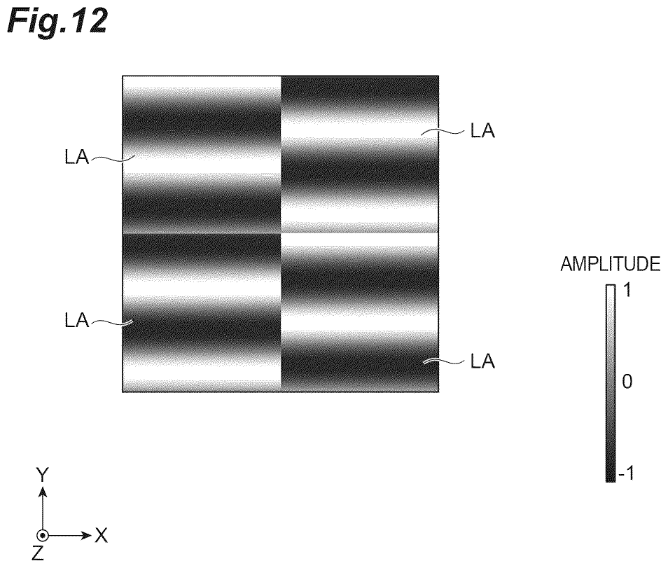

FIG. 12 is a diagram conceptually illustrating another example of the plurality of light images output from the plurality of phase modulation areas 151. A total of four light images LA of 2 columns in the X direction and 2 rows in the Y direction are illustrated in FIG. 12. These are light images which are output from a total of four phase modulation areas 151 of 2 columns in the X direction and 2 rows in the Y direction. In this example, the light intensity distribution of the light images LA output from the phase modulation areas 151 includes a sinusoidal light intensity distribution which varies periodically in the Y direction. The phase in the Y direction of the sinusoidal distribution of the light images LA output from two phase modulation areas 151 located on one diagonal is different from the phase in the Y direction of the sinusoidal light intensity distribution of the light images LA output from two phase modulation areas 151 located on the other diagonal. In this example, by changing a ratio of the magnitude of the driving current of two electrode parts 161 corresponding to the two phase modulation areas 151 located on one diagonal to the magnitude of the driving current of two electrode parts 161 corresponding to the two phase modulation areas 151 located on the other diagonal, it is possible to freely change the phase of the sinusoidal light intensity distribution presented in the final light image. As in the example illustrated in FIG. 12, the phases in only one direction (the Y direction) of the sinusoidal light intensity distribution of the light images LA output from at least two phase modulation areas 151 may be different from each other. The light intensity distribution of the light images LA output from at least two phase modulation areas 151 may include a sinusoidal distribution which varies periodically in two directions (the X direction and the Y direction). In this case, the phase in each direction of the light intensity distribution with a sinusoidal shape of at least two light images LA output from at least two phase modulation areas 151 may differ between the light images LA.

A phase distribution design method in consideration of phase synchronization of light images output from a plurality of phase modulation areas 151 will be described below in detail. In the following description, a plurality of different-refractive-index regions 15b may be referred to as a “plurality of points.” That is, the method described below is a method of designing a phase distribution ϕ(x, y) of two or more phase modulation areas 151 for individually modulating phases of light at a plurality of points which are distributed in a two-dimensional shape. In the following description, a “real space” refers to a space of the phase modulation areas 151, and a “wave number space” refers to a space of light images (also referred to as beam patterns) in an irradiation area.

### [First Design Method]

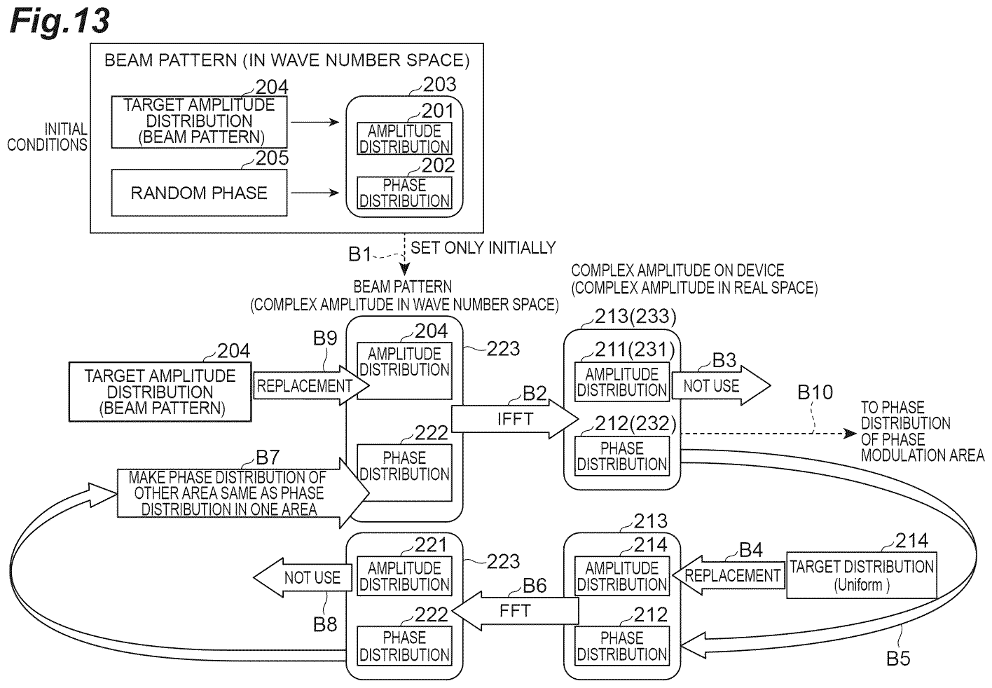

FIG. 13 is a diagram conceptually illustrating a first design method. First, in a first step, initial conditions are set (an arrow B1 in the drawing). A first function 203 which is a complex amplitude distribution function including an initial value 201 of the amplitude distribution in the wave number space and an initial value 202 of the phase distribution in the wave number space is set for each phase modulation area 151. When the initial value 201 of the amplitude distribution in the wave number space is F₀(kx, ky) and the initial value 202 of the phase distribution in the wave number space is θ0(kx, ky), the first function 203 is expressed as F₀(kx, ky)·e^{iθ0(kx,ky)}. At this time, the initial value 201 of the amplitude distribution in the wave number space may be a predetermined target amplitude distribution 204 in the wave number space. When the target amplitude distribution 204 in the wave number space is F₀(kx, ky), a light intensity distribution (that is, a desired light image) is given as F₀²(kx, ky). The initial value 202 of the phase distribution in the wave number space may be a random phase distribution 205.

In the first step, for each phase modulation area 151, the first function 203 is converted to a second function 213 which is a complex amplitude distribution function including an amplitude distribution 211 in the real space and a phase distribution 212 in the real space, for example, using an inverse Fourier transform such as an inverse fast Fourier transform (IFFT) (an arrow B2 in the drawing). When the amplitude distribution 211 in the real space is A(x, y) and the phase distribution 212 in the real space is ϕ(x, y), the second function 213 is expressed as A(x, y)·e^{iϕ(kx,ky)}.

Then, in a second step, the amplitude distribution 211 of the second function 213 in each phase modulation area 151 is replaced with a target amplitude distribution 214 based on a predetermined target intensity distribution in the real space (arrows B3 and B4 in the drawing). For example, when the predetermined target intensity distribution is A₀²(x, y), the target amplitude distribution is given as A₀(x, y). For example, the predetermined target intensity distribution A₀²(x, y) is constant regardless of x and y, and the target amplitude distribution A₀(x, y) is also constant regardless of x and y. In this case, the phase distribution 212 of the second function 213 in each phase modulation area 151 is held without any change (an arrow B5 in the drawing). Then, for each phase modulation area 151, the second function 213 subjected to the replacement is converted to a third function 223 which is a complex amplitude distribution function including an amplitude distribution 221 in the wave number space and a phase distribution 222 in the wave number space, for example, using a Fourier transform such as a fast Fourier transform (FFT) (an arrow B6 in the drawing). When the amplitude distribution 221 in the wave number space is F(kx, ky) and the phase distribution 222 in the wave number space is θ(kx, ky), the third function 223 is expressed as F(kx, ky)·e^{iθ(kx,ky)}.

Then, in a third step, the phase distributions 222 of the third function 223 in the phase modulation areas 151 are made the same as the phase distribution 222 of the third function 223 in one phase modulation area 151 out of the plurality of phase modulation areas 151 (an arrow B7 in the drawing). In this case, the one phase modulation area 151 serving as a reference for making the phase distributions 222 the same is arbitrarily determined. In the third step, the amplitude distribution 221 of the third function 223 in each phase modulation area 151 is replaced with the target amplitude distribution 204 (arrows B8 and B9 in the drawing). Then, for each phase modulation area 151, the third function 223 subjected to the replacement is converted to a fourth function 233 which is a complex amplitude distribution function including an amplitude distribution 231 in the real space and a phase distribution 232 of the real space using an inverse Fourier transform such as an IFFT (an arrow B2 in the drawing). When the amplitude distribution 231 in the real space is A(x, y) and the phase distribution 232 in the real space is ϕ(x, y), the fourth function 233 is expressed as A(x, y)·e^{iϕ(kx,ky)}.

Thereafter, the second step and the third step are repeated while replacing the second function 213 in the second step with the fourth function 233. Whenever the third step is repeated, the position of one phase modulation area 151 serving as a reference for making the phase distribution 222 the same may be fixed without being changed. Then, the phase distribution 232 of the fourth function 233 finally subjected to the conversion in the third step is set as the phase distribution ϕ(x, y) of the phase modulation areas 151 (an arrow B10 in the drawing).

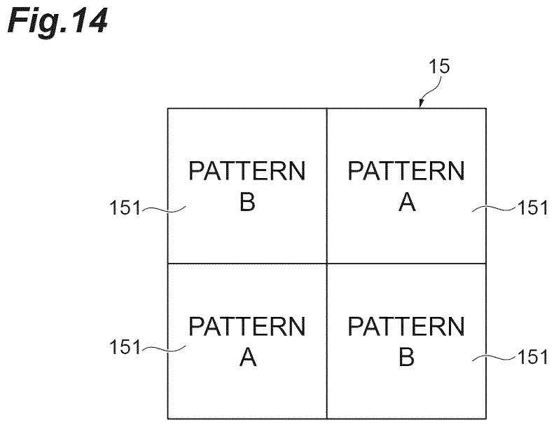

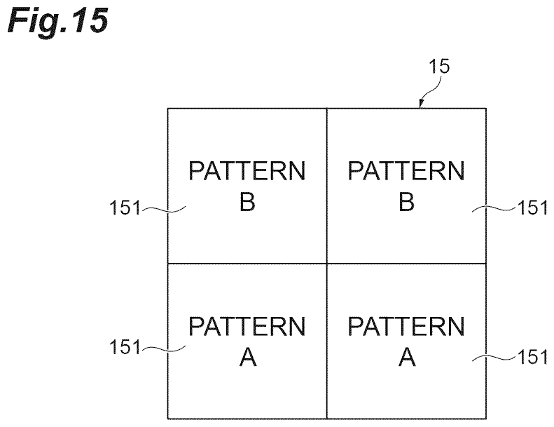

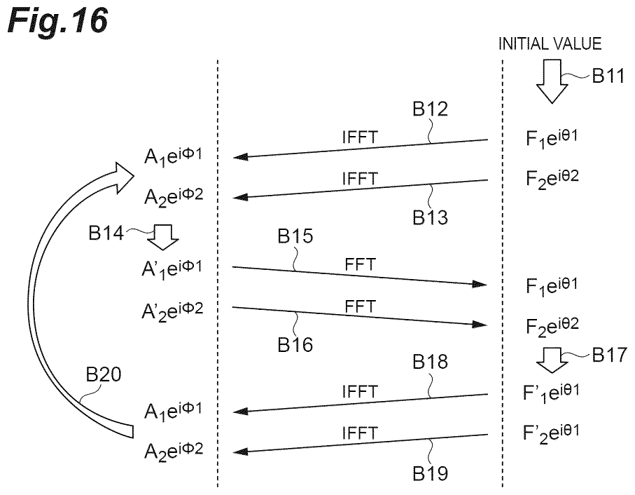

For example, as illustrated in FIG. 14, a phase modulation layer 15 including a total of four phase modulation areas 151 of 2 columns in the X direction and 2 rows in the Y direction is considered. Among these, it is assumed that two phase modulation areas 151 located on one diagonal have a phase distribution pattern A and two phase modulation areas 151 located on the other diagonal have a phase distribution pattern B. Alternatively, as illustrated in FIG. 15, two phase modulation areas 151 included in the first row have a phase distribution pattern B, and two phase modulation areas 151 included in the second row may have a phase distribution pattern A. FIG. 16 is a diagram conceptually illustrating a method of designing phase distribution patterns A and B.

First, in the first step, initial values are set (an arrow B11 in the drawing). That is, a first function F₁(kx, ky)·e^{iθ1(kx,ky)} (hereinafter abbreviated to F₁·e^{iθ1}) which is a complex amplitude distribution function including an initial value of an amplitude distribution F₁(kx, ky) in the wave number space and an initial value of a phase distribution θ1(kx, ky) in the wave number space is set for the phase distribution pattern A. A first function F₂(kx, ky)·e^{iθ2(kx,ky)} (hereinafter abbreviated to F₂·e^{iθ2}) which is a complex amplitude distribution function including an initial value of an amplitude distribution F₂(kx, ky) in the wave number space and an initial value of a phase distribution θ2(kx, ky) in the wave number space is set for the phase distribution pattern B. Then, the first function F₁·e^{iθ1} of the phase distribution pattern A is converted to a second function A₁(x, y)·e^{iϕ1(x,y)} (hereinafter abbreviated to A₁e^{iϕ1}) which is a complex amplitude distribution function including an amplitude distribution A₁(x, y) in the real space and a phase distribution ϕ1(x, y) in the real space through an inverse Fourier transform such as an IFFT (an arrow B12 in the drawing). Similarly, the first function F₂(x, y)·e^{iθ2(x,y)} of the phase distribution pattern B is converted to a second function A₂(x, y)·e^{iθ2(x,y)} (hereinafter abbreviated to A₂·e^{iϕ1}) which is a complex amplitude distribution function including an amplitude distribution A₂(x, y) in the real space and a phase distribution ϕ2(x, y) in the real space through an inverse Fourier transform such as an IFFT (an arrow B13 in the drawing).

Then, in the second step, the amplitude distribution A₁ of the second function A₁·e^{iϕ1} is replaced with a target amplitude distribution A₁′ based on a predetermined target intensity distribution in the real space. Similarly, the amplitude distribution A₂ of the second function A₂·e^{iθ2} is replaced with a target amplitude distribution A₂′ based on a predetermined target intensity distribution in the real space (an arrow B14 in the drawing). At this time, the phase distribution ϕ1 and the phase distribution ϕ2 are held without any change. Then, the second function A₁′·e^{iϕ1} subjected to the replacement is converted to a third function F_{I}·e^{iθ1} which is a complex amplitude distribution function including an amplitude distribution F₁ in the wave number space and a phase distribution θ1 in the wave number space, for example, through a Fourier transform such as an FFT (an arrow B15 in the drawing). Similarly, the second function A₂′·e^{iϕ2} subjected to the replacement is converted to a third function F₂·e^{iθ2} which is a complex amplitude distribution function including an amplitude distribution F₂ in the wave number space and a phase distribution θ2 in the wave number space, for example, through a Fourier transform such as an FFT (an arrow B16 in the drawing).

Then, in the third step, the phase distribution θ2 of the third function F₂·e^{iθ2} is made the same as the phase distribution θ1 of the third function F₁·e^{iθ1}. The amplitude distribution F₁ of the third function F₁·e^{iθ1} and the amplitude distribution F₂ of the third function F₂·e^{iθ2} are replaced with the target amplitude distributions F₁′ and F₂′ (an arrow B17 in the drawing). Then, the third function F₁′·e^{iθ1} is converted to a fourth function A₁·e^{iϕ1} which is a complex amplitude distribution function including the amplitude distribution A₁ in the real space and the phase distribution ϕ1 in the real space through inverse Fourier transform such as an IFFT (an arrow B18 in the drawing). Similarly, the third function F₂′·e^{iθ1} is converted to a fourth function A₂·e^{iϕ2} which is a complex amplitude distribution function including the amplitude distribution A₂ in the real space and the phase distribution ϕ2 in the real space through inverse Fourier transform such as an IFFT (an arrow B19 in the drawing).

Thereafter, the second step and the third step are repeated while replacing the second function A₁·e^{iϕ1} and the second function A₂·e^{iϕ2} in the second step with the fourth function A₁·e^{iϕ1} and the fourth function A₂·e^{iϕ2}, respectively (an arrow B20 in the drawing). Then, the phase distribution ϕ₁ of the fourth function A₁·e^{iϕ1} finally subjected to the conversion in the third step is set as the phase distribution ϕ(x, y) with the phase distribution pattern A. The phase distribution ϕ2 of the fourth function A₂·e^{iϕ2} finally subjected to the conversion in the third step is set as the phase distribution ϕ(x, y) with the phase distribution pattern B.

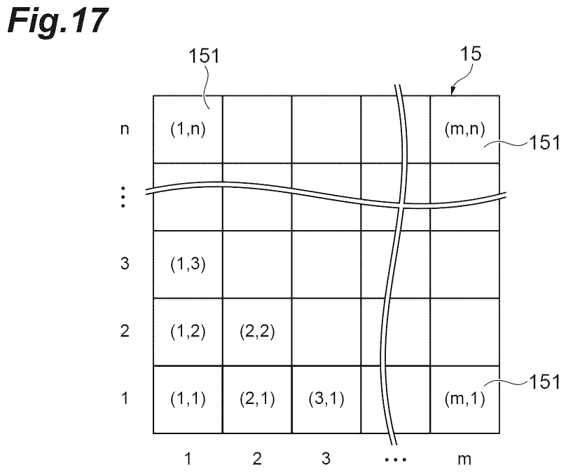

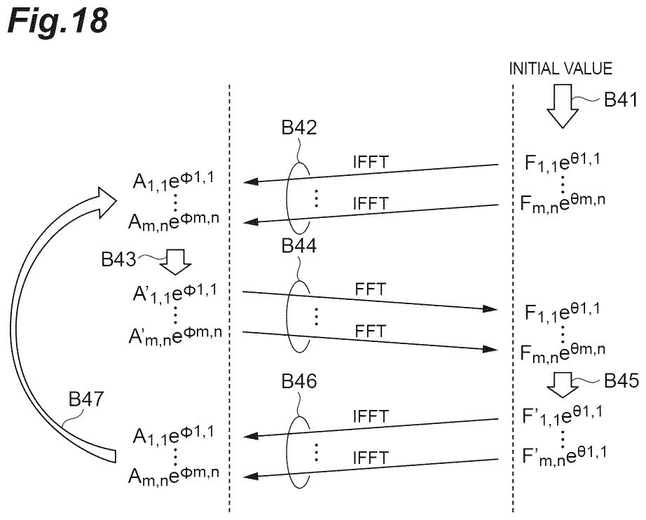

As another example, as illustrated in FIG. 17, a phase modulation layer 15 including a total of m×n phase modulation areas 151 of m columns in the X direction and n rows in the Y direction is considered. The m×n phase modulation areas 151 have different phase distribution patterns. FIG. 18 is a diagram conceptually illustrating a method of designing m×n phase distribution patterns.

First, in the first step, initial values are set (an arrow B41 in the drawing). That is, first functions F_{1,1}(kx, ky)·e^{iθ1,1(kx,ky)} to F_{m,n}(kx, ky)·e^{iθm,n(kx,ky)} (hereinafter abbreviated to F_{1,1}·e^{iθ1,1} to F_{m,n}·e^{iθm,n}) which are complex amplitude distribution functions including initial values of amplitude distributions F_{1,1}(kx, ky) to F_{m,n}(kx, ky) in the wave number space and initial values of phase distributions θ1,1(kx, ky) to θm,n(kx, ky) in the wave number space are set for the m×n phase modulation areas 151. For each phase modulation area 151, the first functions F_{1,1}·e^{iθ1,1} to F_{m,n}·e^{iθm,n} are converted to second functions A_{1,1}(x, y)·e^{iϕ1,1(x,y)} to A_{m,n}(x, y)·e^{iϕm,n(x,y)} (hereinafter abbreviated to A_{1,1}·e^{iϕ1,1}, to A_{m,n}·e^{iϕm,n}) which are complex amplitude distribution functions including amplitude distributions A_{1,1}(x, y) to A_{m,n}(x, y) in the real space and phase distributions ϕ1,1(x, y) to ϕm,n(x, y) in the real space through an inverse Fourier transform such as an IFFT (a group of arrows B42 in the drawing).

Then, in the second step, for each phase modulation area 151, the amplitude distributions A_{1,1} to A_{m,n} of the second functions A_{1,1}·e^{iϕ1,1} to A_{m,n}·e^{iϕm,n} are replaced with target amplitude distributions A′_{1,1}, to A′_{m,n} based on a predetermined target intensity distribution in the real space (an arrow B43 in the drawing). At this time, the phase distributions ϕ1,1 to ϕm,n are held without any change. Then, for each phase modulation area 151, the second functions A′_{1,1}·e^{iϕ1,1} to A′_{m,n}·e^{iϕm,n} subjected to the replacement are converted to third functions F_{1,1}·e^{iθ1,1} to F_{m,n}·e^{iθm,n} which are complex amplitude distribution functions including amplitude distributions F_{1,1} to F_{m,n} in the wave number space and phase distributions θ1,1 to θm,n in the wave number space, for example, through a Fourier transform such as an FFT (a group of arrows B44 in the drawing).

Then, in the third step, all the phase distributions θ1,1 to θm,n of the third functions F_{1,1}·e^{iθ1,1} to F_{m,n}·e^{iθm,n} are made the same as the phase distribution θ1,1 of the third function F_{1,1}·e^{iθ1,1} The amplitude distributions F_{1,1} to F_{m,n} of the third functions F_{1,1}·e^{iθ1,1} to F_{m,n}·e^{iθm,n} are replaced with target amplitude distributions F′_{1,1} to F′_{m,n} (an arrow B45 in the drawing). Then, the third functions F′_{1,1}·e^{iθ1,1} to F′_{m,n}·e^{iθm,n} are converted to fourth functions A_{1,1}·e^{iϕ1,1} to A_{m,n}·e^{iϕm,n} which are complex amplitude distribution functions including the amplitude distributions A_{1,1} to A_{m,n} in the real space and the phase distributions ϕ1,1 to ϕm,n in the real space through an inverse Fourier transform such as an IFFT (a group of arrows B46 in the drawing).

Thereafter, the second step and the third step are repeated while replacing the second functions A_{1,1}·e^{iϕ1,1} to A_{m,n}·e^{iϕm,n} in the second step with the fourth functions A_{1,1}·e^{iϕ1,1} to A_{m,n}·e^{iϕm,n} (an arrow B47 in the drawing). Then, the phase distributions ϕ1,1 to ϕm,n of the fourth functions A_{1,1}·e^{iϕ1,1} to A_{m,n}·e^{iϕm,n} finally subjected to the conversion in the third step are set as the phase distributions ϕ(x, y) of the phase modulation areas 151.

### [Second Design Method]

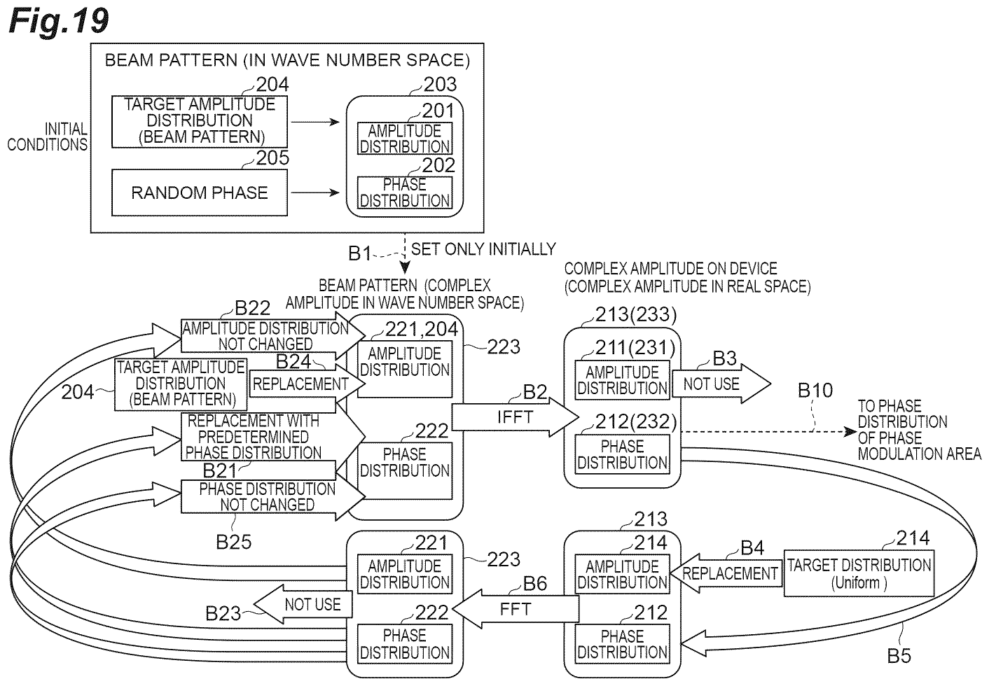

FIG. 19 is a diagram conceptually illustrating a second design method. The first step and the second step are the same as in the first design method, and thus description thereof will be omitted.

In the third step of the first time, the phase distribution 222 of the third function 223 in each phase modulation area 151 is replaced with a predetermined phase distribution which is the same in the plurality of phase modulation areas 151 (a first procedure, an arrow B21 in the drawing). The phase values of a plurality of points (kx, ky) in the predetermined phase distribution may be the same. In this case, the phase values of the plurality of points (kx, ky) in the predetermined phase distribution may be zero (0 rad). At this time, the amplitude distribution 221 is held without any change (an arrow B22 in the drawing). Then, the third function 223 is converted to the fourth function 233 through an inverse Fourier transform such as an IFFT (an arrow B2 in the drawing).

The second function 213 is replaced with the fourth function 233 and the second step is performed again. Thereafter, in the third step (of the second time), the amplitude distribution 221 of the third function 223 is replaced with the target amplitude distribution 204 (a second procedure, arrows B23 and B24 in the drawings). At this time, the phase distribution 222 is held without any change (an arrow B25 in the drawing). Then, the third function 223 subjected to the replacement is converted to the fourth function 233 through an inverse Fourier transform such as an IFFT (an arrow B2 in the drawing).

Thereafter, the second step and the third step are repeatedly performed while replacing the second function 213 of the second step with the fourth function 233. At that time, in repetition of the third step, replacement of the phase distribution 222 with the predetermined phase distribution (the first procedure) and replacement of the amplitude distribution 221 with the target amplitude distribution 204 (the second procedure) are alternately performed. In the first procedure of a plurality of times in which the third step is repeated, the predetermined phase distribution may be fixed without being changed. The phase distribution 232 of the fourth function 233 finally subjected to the replacement in the third step is set as the phase distribution ϕ(x, y) of each phase modulation area 151 (an arrow B10 in the drawing).

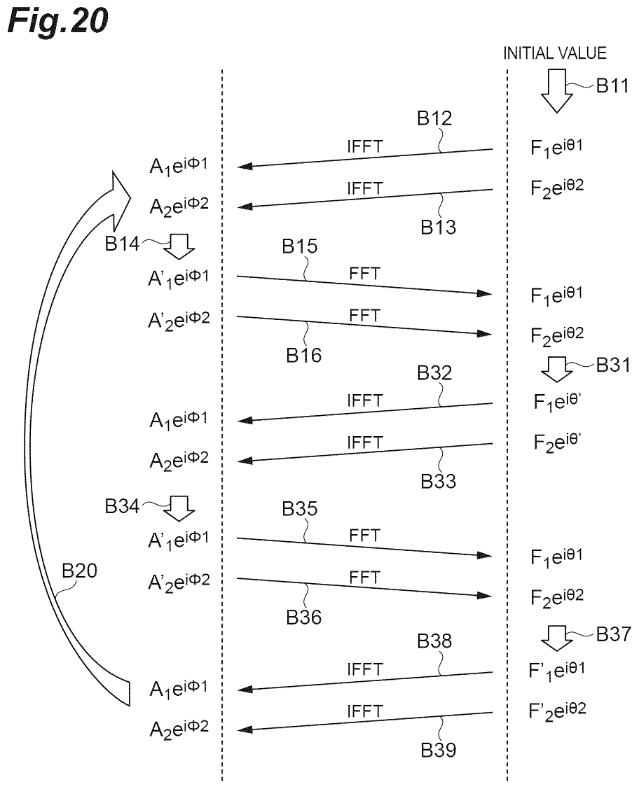

For example, as illustrated in FIG. 14 or 15, the phase modulation layer 15 including a total of four phase modulation areas 151 of 2 columns in the X direction and 2 rows in the Y direction is considered. Among these, two phase modulation areas 151 have a phase distribution pattern A and two phase modulation areas 151 have a phase distribution pattern B. FIG. 20 is a diagram conceptually illustrating a method of designing the phase distribution patterns A and B. The first step and the second step are the same as in the first design method, and thus description thereof will be omitted.

In the third step of the first time, the phase distribution θ1 of the third function F₁·e^{iθ1} and the phase distribution θ2 of the third function F₂·e^{iθ2} are replaced with a predetermined phase distribution θ′ common to the phase distribution pattern A and the phase distribution pattern B (an arrow B31 in the drawing). At that time, the amplitude distribution F₁ and the amplitude distribution F₂ are held without any change. Then, the third function F₁·e^{iθ′} and the third function F₂·e^{iθ′} are converted to the fourth function A₁·e^{iϕ1} and the fourth function A₂·e^{iθ2}, respectively, through an inverse Fourier transform such as an IFFT (arrows B32 and B33 in the drawing).

The second step is performed again while replacing the second function A₁·e^{iϕ1} and the second function A₂·e^{iθ2} with the fourth function A₁·e^{iϕ1} and the fourth function A₂·e^{iθ2}, respectively (arrows B34 to B36 in the drawing). Thereafter, in the third step (of the second time), the amplitude distribution F₁ of the third function F₁·e^{iθ1} and the amplitude distribution F₂ of the third function F₂·e^{iθ2} are replaced with the target amplitude distributions F₁′ and F₂′, respectively (an arrow B37 in the drawing). Then, the third function F₁′·e^{iθ1} and the third function F₂′·e^{iθ2} are converted to the fourth function A₁·e^{iϕ1} and the fourth function A₂·e^{iθ2}, respectively, through an inverse Fourier transform such as an IFFT (arrows B38 and B39 in the drawing).

Thereafter, the second step and the third step are repeated while replacing the second function A₁·e^{iϕ1} and the second function A₂·e^{iϕ2} in the second step with the fourth function A₁·e^{iϕ1} and the fourth function A₂·e^{iϕ2}, respectively (an arrow B20 in the drawing). At that time, in repetition of the third step, replacement of the phase distributions θ1 and θ2 (the first procedure, an arrow B31 in the drawing) and replacement of the amplitude distributions F₁ and F₂ (the second procedure, an arrow B37 in the drawing) are alternately performed. Then, the phase distribution ϕ1 of the fourth function A₁·e^{iϕ1} finally subjected to the conversion in the third step is set as the phase distribution ϕ(x, y) with the phase distribution pattern A. The phase distribution ϕ2 of the fourth function A₂·e^{iϕ2} finally subjected to the conversion in the third step is set as the phase distribution ϕ(x, y) with the phase distribution pattern B.

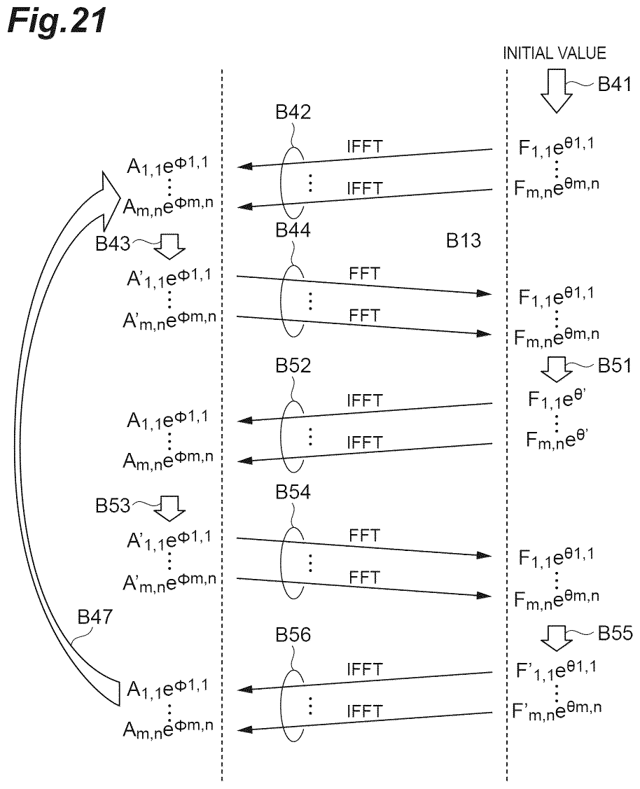

As another example, as illustrated in FIG. 17, the phase modulation layer 15 including a total of m×n phase modulation areas 151 of m columns in the X direction and n rows in the Y direction is considered. The m×n phase modulation areas 151 have different phase distribution patterns. FIG. 21 is a diagram conceptually illustrating a method of designing the m×n phase distribution patterns. The first step and the second step are the same as in the first design method, and thus description thereof will be omitted.

In the third step of the first time, all the phase distributions θ1,1 to θm,n of the third functions F_{1,1}·e^{iθ1,1} to F_{m,n}·e^{iθm,n} are replaced with a predetermined common phase distribution θ′ (the first procedure, an arrow B51 in the drawing). At this time, amplitude distributions F_{1,1} to F_{m,n} are held without any change. Then, the third functions F_{1,1}·e^{iθ′} to F_{m,n}·e^{iθ′} are converted to the fourth functions A_{1,1}·e^{iϕ1,1} to A_{m,n}·e^{iϕm,n} respectively, through an inverse Fourier transform such as an IFFT (a group of arrows B52 in the drawing).

The second step is performed again after replacing the second functions A_{1,1}·e^{iϕ1,1} to A_{m,n}·e^{iϕm,n} with the fourth functions A_{1,1}·^{iϕ1,1} to A_{m,n}·e^{iϕm,n}, respectively (an arrow B53 and a group of arrows B54 in the drawing). Thereafter, in the third step (of the second time), the amplitude distributions F_{1,1} to F_{m,n} of the third functions F_{1,1}·e^{iθ1,1} to F_{m,n}·e^{iθm,n} are replaced with the target amplitude distributions F′_{1,1} to F′_{m,n}, respectively (the second procedure, an arrow B55 in the drawing). Then, the third functions F′_{1,1}·e^{iθ1,1} to F′_{m,n}·e^{iθm,n} are converted to the fourth functions A_{1,1}·e^{iϕ1,1} to A_{m,n}·e^{iϕm,n}, respectively, through an inverse Fourier transform such as an IFFT (a group of arrows B56 in the drawing).

Thereafter, the second step and the third step are repeated while replacing the second functions A_{1,1}·e^{iϕ1,1} to A_{m,n}·e^{iϕm,n} in the second step with the fourth functions A_{1,1}·e^{iϕ1,1} to A_{m,n}·e^{iϕm,n}, respectively (an arrow B47 in the drawing). At that time, in repetition of the third step, replacement of the phase distributions θ1,1 to θm,n (the first procedure, an arrow B51 in the drawing) and replacement of the amplitude distributions F_{1,1} to F_{m,n} (the second procedure, an arrow B55 in the drawing) are alternately performed. Then, the phase distributions θ1,1 to θm,n of the fourth functions A_{1,1}·e^{iϕ1,1} to A_{m,n}·e^{iϕm,n} finally subjected to the conversion in the third step are set as the phase distributions ϕ(x, y) of the phase modulation areas 151.

Advantageous effects obtained from the semiconductor light-emitting element 1 according to the embodiment described above will be described below. In the semiconductor light-emitting element 1, one or both of the electrode 16 and the electrode 17 include a plurality of electrode parts (for example, the plurality of electrode parts 161) overlapping a plurality of phase modulation areas 151. The plurality of electrode parts are electrically isolated from each other. Accordingly, independent currents can be supplied to the plurality of electrode parts. As a result, it is possible to independently control light emission intensities of a plurality of areas of the active layer 12 for supplying light to the plurality of phase modulation areas 151 and to independently control light intensities of the plurality of light images LA output from the plurality of phase modulation areas 151. The plurality of light images LA are applied to a common irradiation area. At this time, since the light images LA output from the plurality of phase modulation areas 151 are synchronized in phase with each other, the plurality of light images LA can interfere with each other in the common irradiation area. In this way, with the semiconductor light-emitting element 1 according to this embodiment, it is possible to form one final light image by causing the plurality of light images LA to interfere with each other while individually adjusting the light intensities of the plurality of light images LA output from the plurality of phase modulation areas 151. Accordingly, it is possible to dynamically change a final light image.

As described above, a light intensity distribution of the light image LA output from each of the plurality of phase modulation areas 151 may include a sinusoidal distribution of which a period or phase in at least one direction differs for each phase modulation area in at least two phase modulation areas of the plurality of phase modulation areas 151. Alternatively, a light intensity distribution of the light image LA output from each of the plurality of phase modulation areas 151 may include a sinusoidal distribution of which a period or phase in two directions perpendicular to each other differs for each phase modulation area in at least two phase modulation areas of the plurality of phase modulation areas 151. In this case, it is possible to obtain an arbitrary final light image by superimposing the plurality of light images LA output from the plurality of phase modulation areas 151 on each other while individually adjusting the light intensities of the plurality of light images LA. Particularly, when the period of the sinusoidal distribution differs for each phase modulation area, the plurality of light images LA output from the plurality of phase modulation areas 151 can serve as a plurality of base images in a discrete cosine transform (DCT).

As in this embodiment, a virtual tetragonal lattice along the virtual plane P is set and a straight line D passing through a corresponding lattice point O and being oblique by the same angle β with respect to the tetragonal lattice is set for each of a plurality of lattice points O of the tetragonal lattice. At that time, the centroids G of the plurality of different-refractive-index regions 15b may be disposed on the corresponding straight line D in each of the plurality of phase modulation areas 151, and a distance r(x, y) between the centroids G of each of the plurality of different-refractive-index regions 15b and the corresponding lattice point O of each of the plurality of different-refractive-index regions 15b may be individually set according to a predetermined light image LA. For example, with this configuration, the plurality of parts of the semiconductor light-emitting element 1 including a phase modulation area 151 can constitute S-iPM lasers and output different predetermined light images LA. It is also possible to align polarization directions of the plurality of phase modulation areas 151.

As in this embodiment, the phase modulation layer 15 may further include a connection area 152 located between the neighboring phase modulation areas 151. The connection area 152 may include a basic region 15a with the first refractive index and a plurality of different-refractive-index regions 15b with the second refractive index, and the centroids of the plurality of different-refractive-index regions 15b of the connection area 152 may be located at the lattice points O of the tetragonal lattice. In this case, since a gap is provided between the neighboring phase modulation areas 151, it is possible to widen gaps between a plurality of electrode parts 161. Accordingly, it is possible to reduce so-called inter-area crosstalk in which a part of currents to be supplied to the areas of the active layer 12 for supplying light to the phase modulation areas 151 leak to neighboring areas. Since the centroids G of the plurality of different-refractive-index regions 15b of the connection area 152 are located at the lattice points O of the tetragonal lattices, it is possible to synchronize phases of the light images LA output from the plurality of phase modulation areas 151 with each other.

As in this embodiment, a planar shape of the connection area 152 when seen in a stacking direction of the semiconductor stacked layer 20 may be a lattice shape. In this case, since a gap can be provided between all the phase modulation areas 151, it is possible to more effectively reduce the inter-area crosstalk.

As in this embodiment, the semiconductor stacked layer 20 may be provided on the main surface 10a of the semiconductor substrate 10, and the second face 20b of the semiconductor stacked layer 20 may be opposite to the main surface 10a of the semiconductor substrate 10. The electrode 16 may be provided on the first face 20a and include the plurality of electrode parts 161, and the electrode 17 may be provided on the rear surface 10b of the semiconductor substrate 10. In this way, since the plurality of electrode parts 161 are provided on the surface opposite to the semiconductor substrate 10 with respect to the semiconductor stacked layer 20, it is possible to decrease distances between the plurality of electrode parts 161 and the active layer 12. Accordingly, it is possible to reduce the inter-area crosstalk.

### First Modified Example

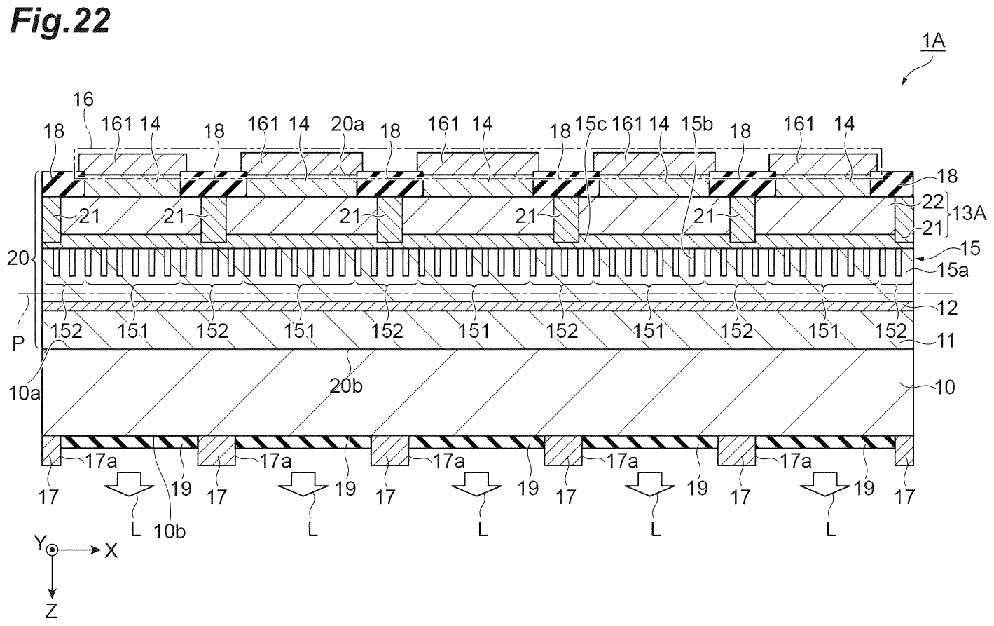

FIG. 22 is a sectional view illustrating a stacked structure of a semiconductor light-emitting element 1A according to a first modified example of the embodiment. The semiconductor light-emitting element 1A is different from that according to the embodiment in that the semiconductor stacked layer 20 includes a clad layer 13A instead of the clad layer 13. The arrangement of the clad layer 13A is the same as the clad layer 13. The other constituents of the semiconductor light-emitting element 1A are the same as in the embodiment, and thus detailed description thereof will be omitted. In this modified example, the electrode 16 necessarily includes the plurality of electrode parts 161.

The clad layer 13A includes a high-resistance region 21 and a basic region 22. The configuration of the basic region 22 is the same as the clad layer 13 according to the embodiment. The high-resistance region 21 has a higher resistivity than the basic region 22. The high-resistance region 21 may be formed of an insulator.

The high-resistance region 21 is located between the neighboring phase modulation areas 151 when seen in the stacking direction of the semiconductor stacked layer 20. The high-resistance region 21 is provided on the connection area 152 of the phase modulation layer 15. An area formed by projecting the high-resistance region 21 onto a virtual plane P is included in an area formed by projecting the connection area 152 onto the virtual plane P. When the phase modulation layer 15 is provided between the clad layer 13A and the active layer 12 as illustrated in the drawing, the high-resistance region 21 extends from a boundary of the clad layer 13A on the first face 20a side to the cap region 15c of the phase modulation layer 15. Here, the high-resistance region 21 is not in contact with the basic region 15a and the different-refractive-index regions 15b. In other words, in the stacking direction (the Z direction) of the semiconductor stacked layer 20, a gap is provided between the high-resistance region 21 and the basic region 15a and the different-refractive-index regions 15b.

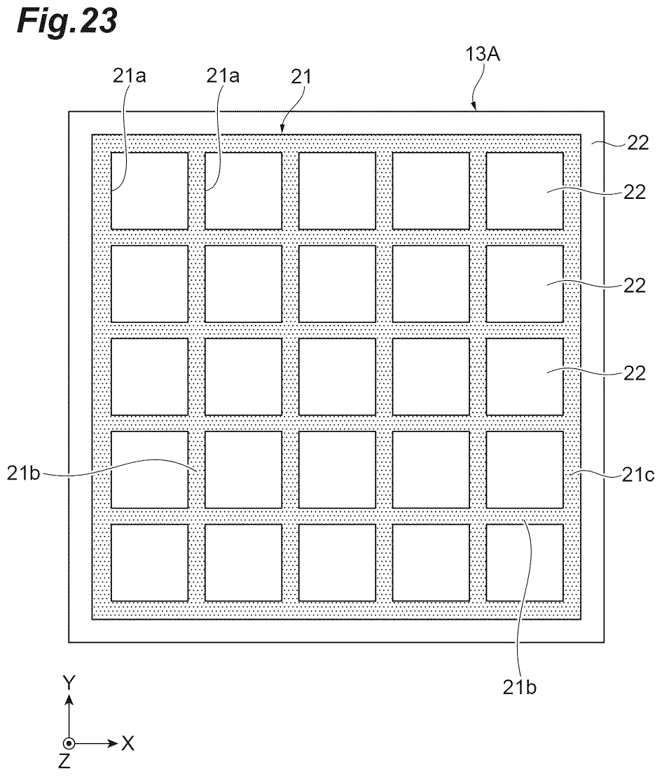

FIG. 23 is a plan view (a view in the thickness direction) of the clad layer 13A. As described above, the clad layer 13A includes the high-resistance region 21 and the basic region 22. The planar shape of the high-resistance region 21 when seen in the stacking direction of the semiconductor stacked layer 20 is, for example, a lattice shape. The basic region 22 is provided inside of a plurality of openings 21a of the high-resistance region 21 which are formed in a lattice shape.

The planar shape of each of the plurality of openings 21a is, for example, a square shape or a rectangular shape. When seen in the stacking direction of the semiconductor stacked layer 20, each of the plurality of openings 21a overlaps the corresponding phase modulation area 151. The high-resistance region 21 includes a part 21b provided between the neighboring phase modulation areas 151 and an outer frame-shaped part 21c surrounding all of the plurality of phase modulation areas 151 when seen in the stacking direction of the semiconductor stacked layer 20.

The high-resistance region 21 illustrated in FIG. 22 passes through the basic region 22 and reaches the phase modulation layer 15, but the high-resistance region 21 may not reach the phase modulation layer 15. In this case, the lowest end of the high-resistance region 21 is located in the basic region 22.

As in this modified example, the clad layer of the semiconductor stacked layer may include the high-resistance region 21 located between the neighboring phase modulation areas 151 when seen in the stacking direction of the semiconductor stacked layer. In this case, it is possible to reduce so-called inter-area crosstalk in which a current flowing between each electrode part 161 and the area of the active layer 12 located just below the electrode part 161 leaks to the area of the active layer 12 located just below the neighboring electrode part 161.

As in this modified example, the high-resistance region 21 may extend from the boundary of the clad layer 13A on the first face 20a side to the phase modulation layer 15. In this case, since leakage of a current can be prevented in the whole area in the thickness direction of the clad layer 13A, it is possible to more effectively reduce the inter-area crosstalk.

As in this modified example, the planar shape of the high-resistance region 21 when seen in the stacking direction of the semiconductor stacked layer 20 may be a lattice shape. In this case, since the high-resistance region 21 can be provided between all the phase modulation areas 151 when seen in the stacking direction, it is possible to more effectively reduce the inter-area crosstalk.

### Second Modified Example

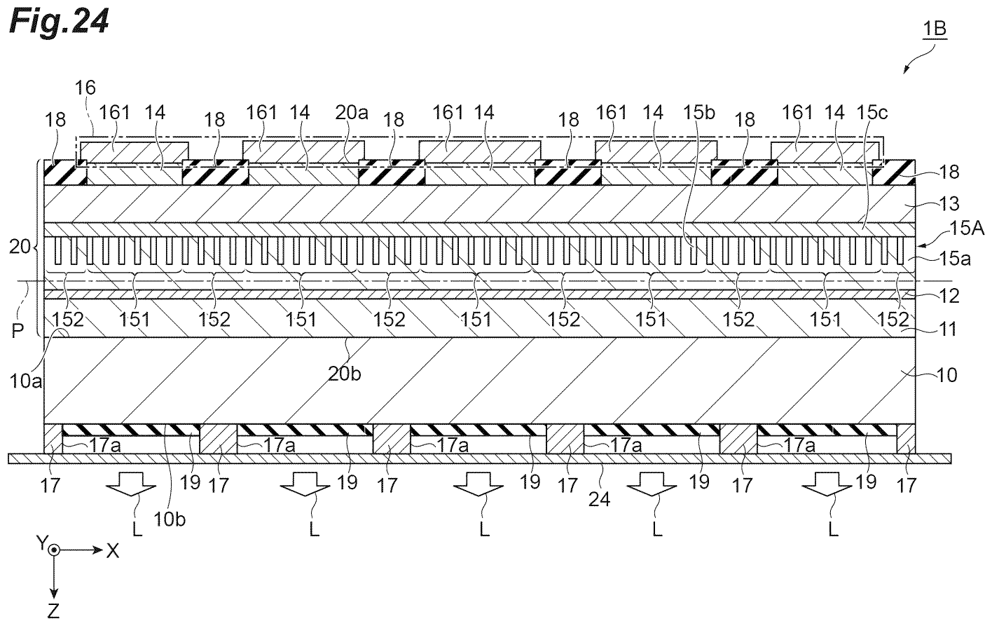

FIG. 24 is a sectional view illustrating a configuration of a semiconductor light-emitting element 1B according to a second modified example of the embodiment. The semiconductor light-emitting element 1B is different from that according to the embodiment in that a phase modulation layer 15A is provided instead of the phase modulation layer 15 and a λ/4 plate 24 is provided. The λ/4 plate 24 extends along the virtual plane P and is disposed to face the rear surface 10b of the semiconductor substrate 10, that is, a light emission surface of the semiconductor light-emitting element 1B. An axis of the λ/4 plate 24 is perpendicular to the straight line D illustrated in FIGS. 3 and 4.

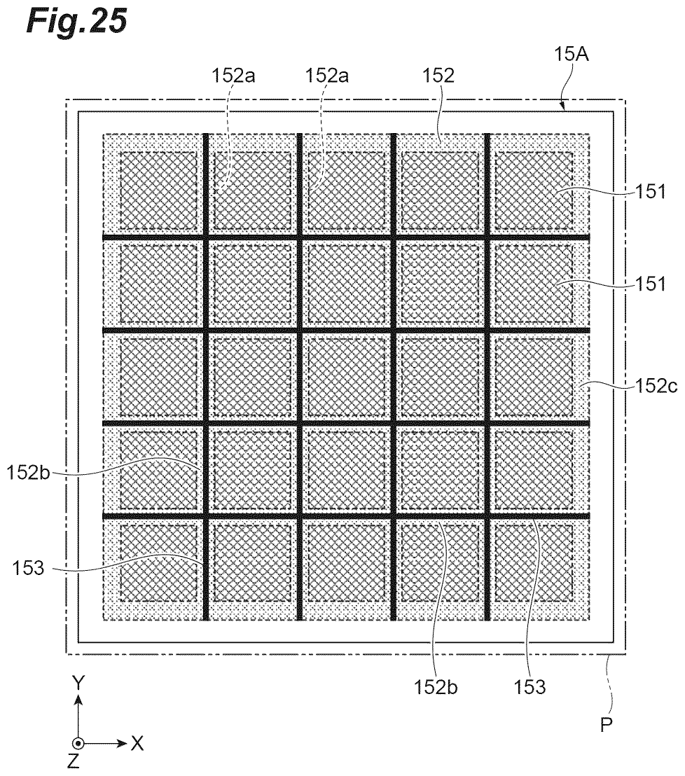

FIG. 25 is a plan view of the phase modulation layer 15A. The phase modulation layer 15A further includes a phase shift area 153 in addition to the configuration of the phase modulation layer 15 according to the embodiment. The phase shift area 153 is provided between the neighboring phase modulation areas 151. In the illustrated example, the phase shift area 153 is provided inside of the part 152b of the connection area 152 and is formed by causing a plurality of parts extending in the X direction and a plurality of parts extending in the Y direction to cross each other. The planar shape of the phase shift area 153 when seen in the stacking direction of the semiconductor stacked layer 20 is, for example, a lattice shape.

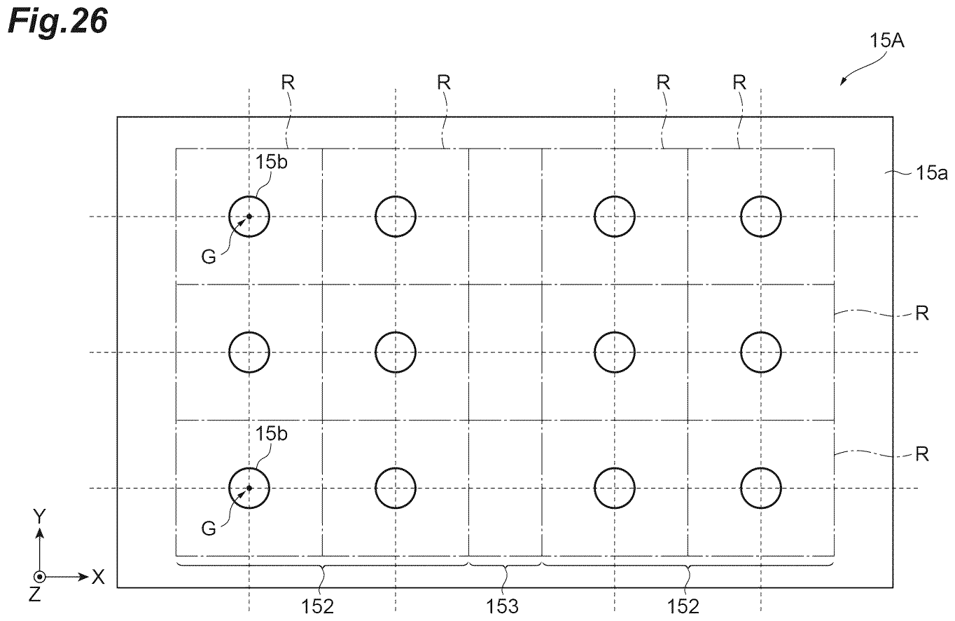

FIG. 26 is a partially enlarged plan view of the phase shift area 153 and the connection area 152 near the phase shift area. As illustrated in FIG. 26, the phase shift area 153 is provided between a tetragonal lattice set in the connection area 152 located on one side of the phase shift area 153 and a tetragonal lattice set in the connection area 152 located on the other side. The phase shift area 153 has an arbitrary width. The tetragonal lattice set in the connection area 152 located on one side of the phase shift area 153 and the tetragonal lattice set in the connection area 152 located on the other side are offset from each other according to the width of the phase shift area 153. These tetragonal lattices are common to the tetragonal lattices set in the phase modulation areas 151 adjacent to the connection area 152. Accordingly, the tetragonal lattices of the neighboring phase modulation areas 151 are offset from each other.

For example, when a lattice constant of the tetragonal lattice is a, the phase shift area 153 has a width of n·a+a/2 (where n is an integer equal to or greater than 0). Accordingly, the tetragonal lattice set in the connection area 152 located on one side of the phase shift area 153 and the tetragonal lattice set in the connection area 152 located on the other side are offset from each other by n·a+a/2. As a result, the tetragonal lattices of the neighboring phase modulation areas 151 are offset from each other by n·a+a/2. In this case, the phases of light images LA output from the neighboring phase modulation areas 151 are offset from each other by π (rad). Accordingly, by causing these light images LA to pass through the λ/4 plate 24, it is possible to output circularly polarized light in the opposite directions from neighboring phase modulation areas 151. As a result, it is possible to electrically change an intensity ratio between left-turn circularly polarized light and right-turn circularly polarized light. This semiconductor light-emitting element can be used as, for example, a light source of photon communication or a quantum computer.

### Third Modified Example

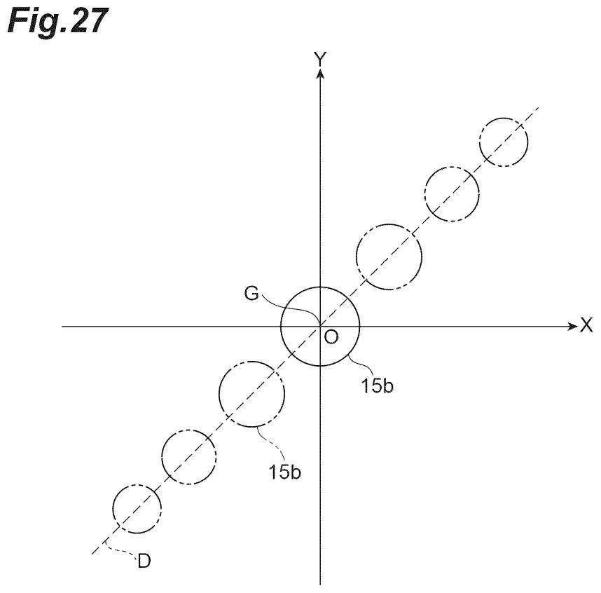

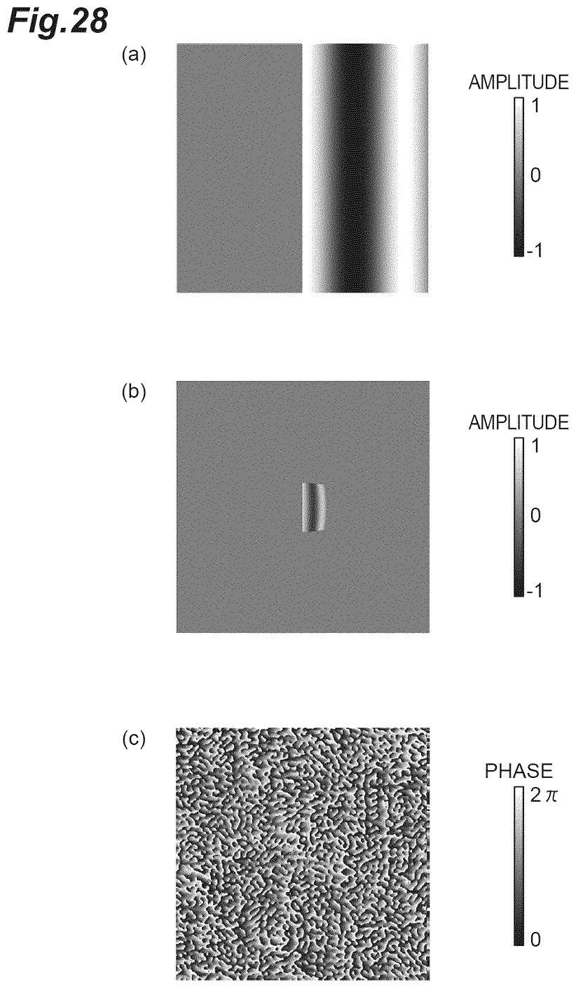

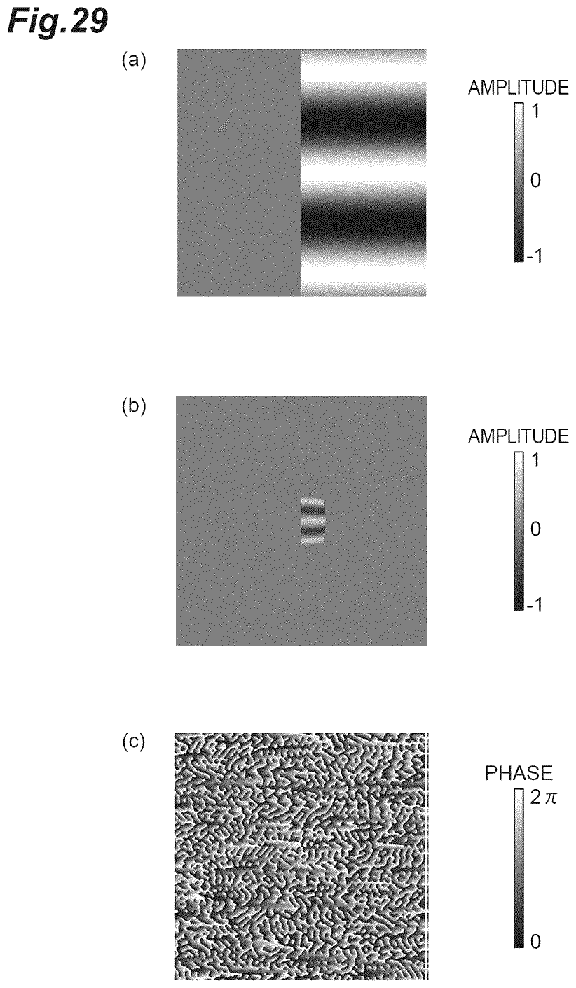

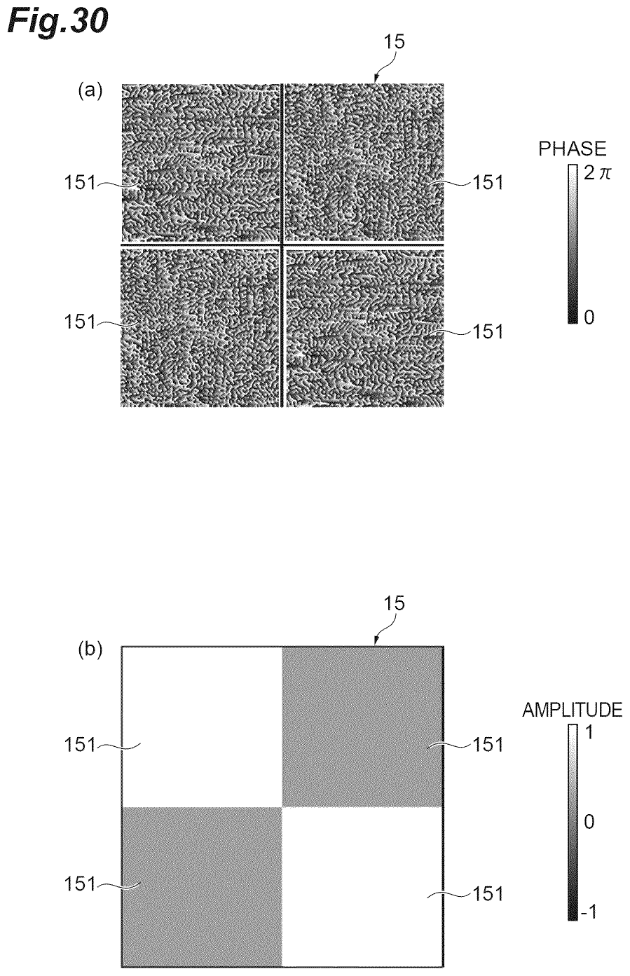

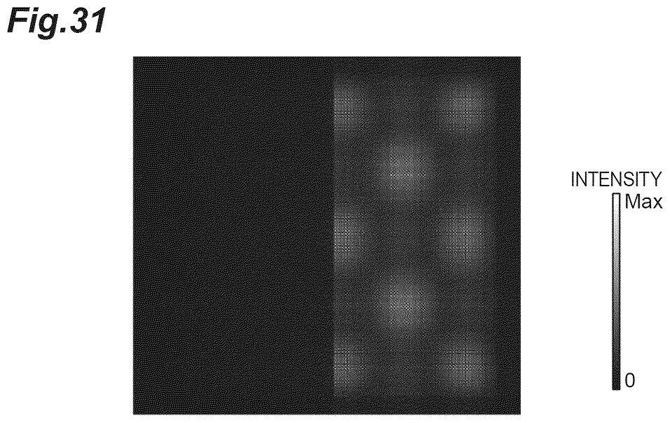

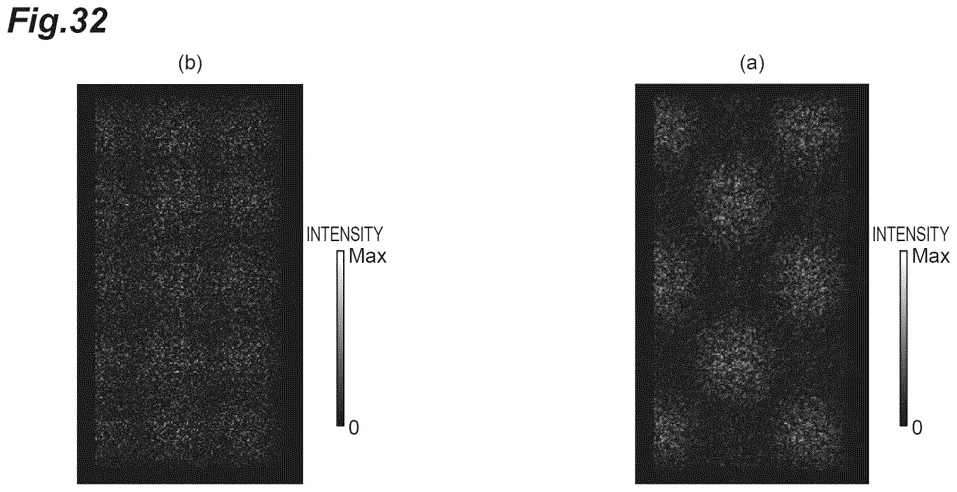

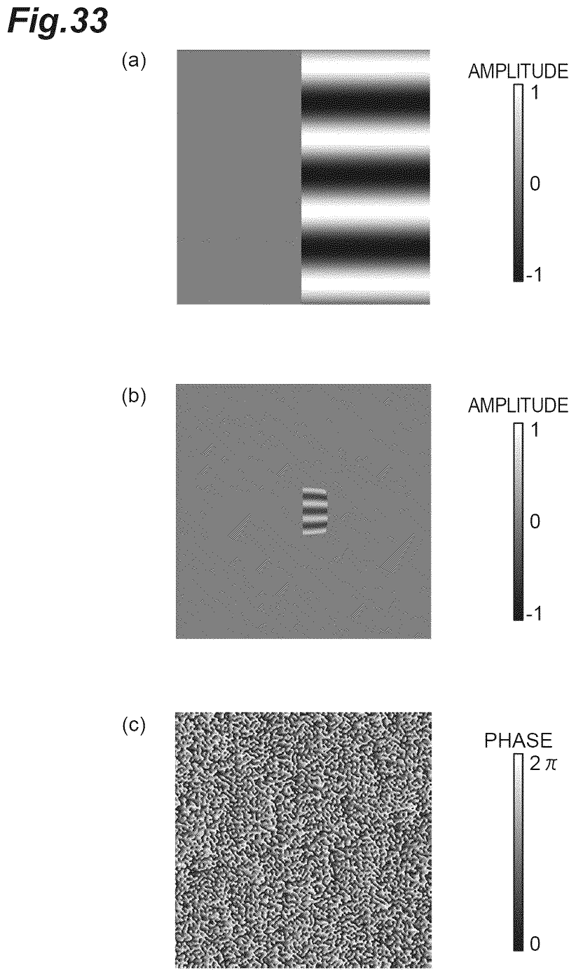

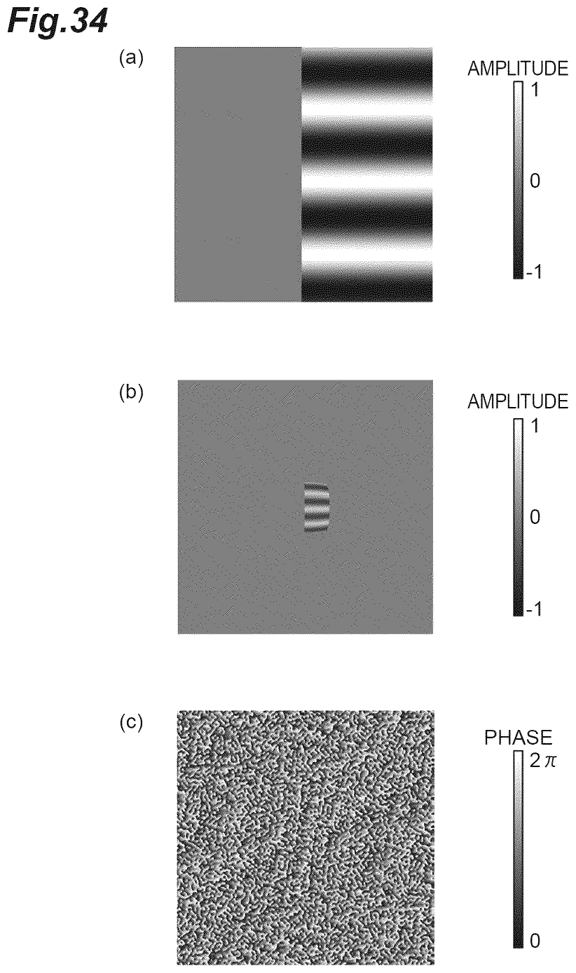

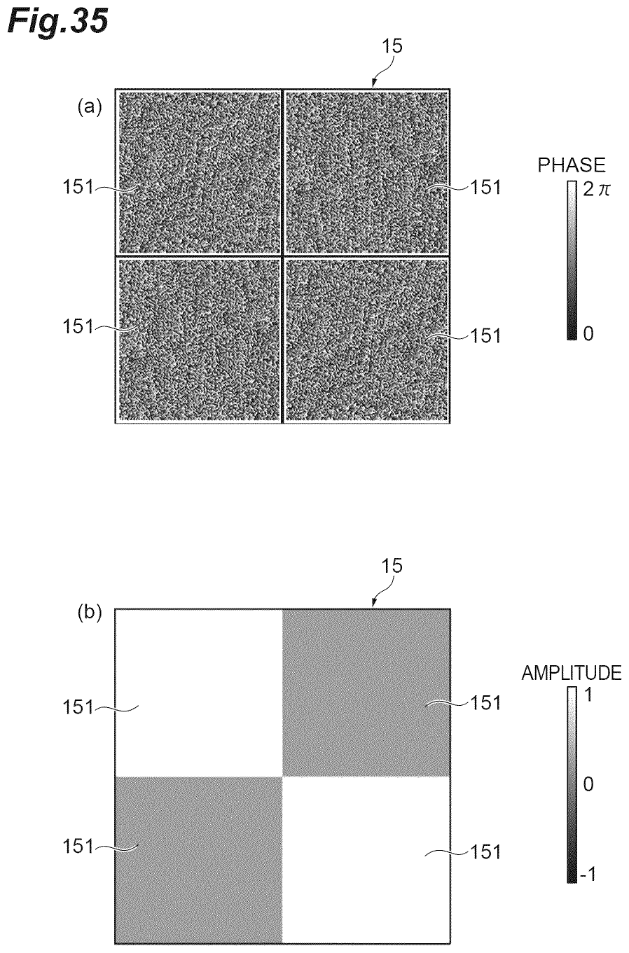

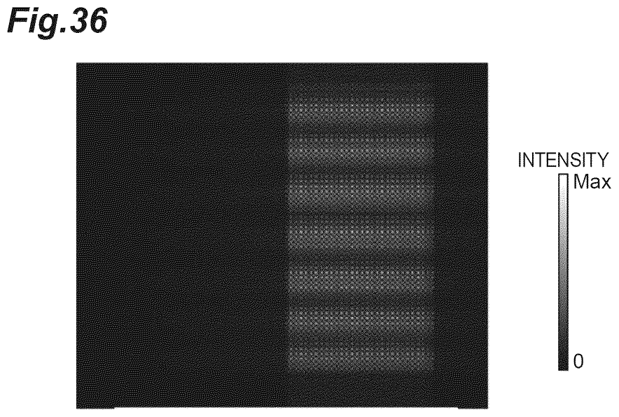

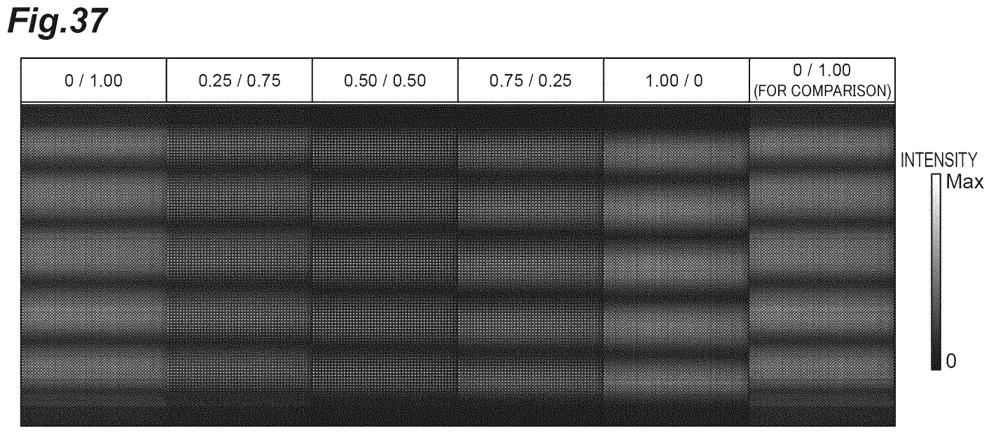

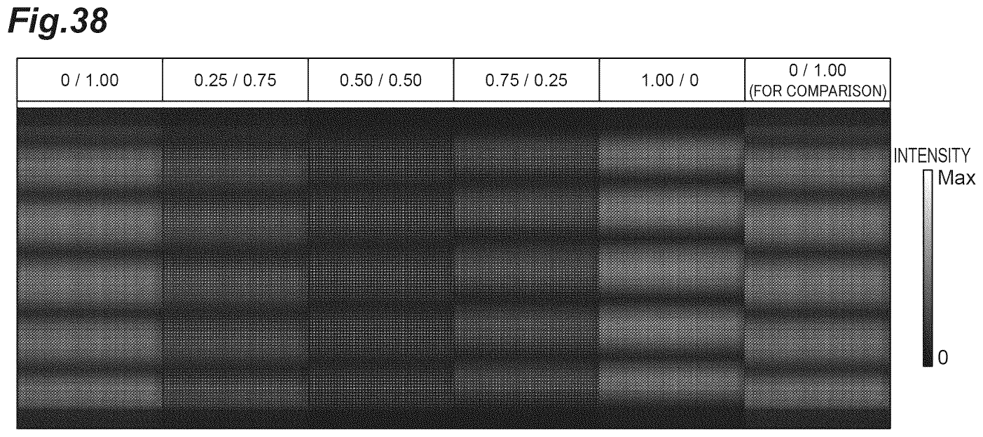

The areas of the plurality of different-refractive-index regions 15b on a section perpendicular to the thickness direction of the phase modulation layer 15 may be individually set according to a predetermined light image LA. In this case, since the light intensity in addition to the phase can be adjusted for each different-refractive-index region 15b, it is possible to enhance a degree of freedom in design of light images LA. FIG. 27 is an enlarged view of one unit constituent area R. In the example illustrated in the drawing, the area of the different-refractive-index region 15b is the largest when the centroid G of the different-refractive-index region 15b matches the lattice point O, and the area of the different-refractive-index region 15b becomes smaller as the centroid G of the different-refractive-index region 15b becomes apart from the lattice point O (that is, as the distance r(x, y) becomes larger). In this way, the area of the different-refractive-index region 15b may be changed according to the relative position of the centroid G of the different-refractive-index region 15b with respect to the lattice point O. Accordingly, it is possible to make the light intensity constant regardless of the phase distribution ϕ(x, y).

### First Example

The inventor performed phase distribution design simulation by employing the phase distribution design method according to the embodiment for the phase modulation layer 15 including four phase modulation areas 151 illustrated in FIG. 14. Part (a) of FIG. 28 illustrates a desired light image in an irradiation area (a far field) which was set when the phase distribution pattern A was designed. In part (a) of FIG. 28, the light intensity becomes larger as the color becomes lighter, and the light intensity becomes smaller as the color becomes darker. As illustrated in part (a) of FIG. 28, a goal of the phase distribution pattern A is to form a light image having a sinusoidal light intensity distribution in which a light intensity changes periodically in only one direction. Part (b) of FIG. 28 illustrates a distribution obtained by converting the light image illustrated in part (a) to the wave number space, that is, a target amplitude distribution in the wave number space. Part (c) of FIG. 28 is a diagram illustrating the phase distribution pattern A which was calculated on the basis of the target amplitude distribution illustrated in part (b). In part (c) of FIG. 28, the phase becomes closer to 2π (rad) as the color becomes lighter, and the phase becomes closer to 0 (rad) as the color becomes darker.

Part (a) of FIG. 29 illustrates a desired light image in an irradiation area (a far field) which was set when the phase distribution pattern B was designed. In part (a) of FIG. 29, the light intensity becomes larger as the color becomes lighter, and the light intensity becomes smaller as the color becomes darker. As illustrated in part (a) of FIG. 29, a goal of the phase distribution pattern B was to form a light image having a sinusoidal light intensity distribution in which a light intensity changes periodically in only a direction perpendicular to a changing direction of the light intensity in part (a) of FIG. 28. Here, the period of the sinusoidal wave was set to the same as in part (a) of FIG. 28. Part (b) of FIG. 29 illustrates a distribution obtained by converting the light image illustrated in part (a) to the wave number space, that is, a target amplitude distribution in the wave number space. Part (c) of FIG. 29 is a diagram illustrating a phase distribution pattern B which was calculated on the basis of the target amplitude distribution illustrated in part (b). In part (c) of FIG. 29, the phase becomes closer to 2π (rad) as the color becomes lighter, and the phase becomes closer to 0 (rad) as the color becomes darker.

Part (a) of FIG. 30 is a diagram illustrating an example in which the phase distribution pattern A was applied to two phase modulation areas 151 located on one diagonal and the phase distribution pattern B was applied to two phase modulation areas 151 located on the other diagonal. Part (b) of FIG. 30 is a diagram conceptually illustrating a difference between a light intensity in the two phase modulation areas 151 located on one diagonal and a light intensity in the two phase modulation areas 151 located on the other diagonal which is realized by individually controlling currents of the electrode parts 161. In part (b) of FIG. 30, the light intensity becomes larger as the color become lighter, and the light intensity becomes smaller as the color becomes darker.

FIG. 31 is a diagram illustrating a final light image which is supposed when a light image emitted from two phase modulation areas 151 having the phase distribution pattern A (see part (a) of FIG. 28) and a light image emitted from two phase modulation areas 151 having the phase distribution pattern B (see part (a) of FIG. 29) are caused to interfere with each other. When these light images are caused to interfere with each other, peaks of the light intensities mutually strengthen each other and bottoms of the light intensities mutually weaken each other, and thus it is expected to obtain a light intensity distribution like a checkboard pattern.

FIG. 32 is a diagram illustrating a final light image acquired through this simulation. Part (a) of FIG. 32 illustrates a light image which is acquired using the first design method according to the embodiment. Part (b) of FIG. 32 illustrates a light image which is acquired using the second design method according to the embodiment. Through comparison of these diagrams, it can be seen that the checkboard pattern based on the second design method is clearer. It can be seen that the checkboard pattern based on the first design method is clearer than that based on the second design method. In this simulation, when the checkboard pattern becomes clearer, it represents that phase synchronization is more appropriately performed and the light images interfere with each other more accurately. Accordingly, with the first design method or the second design method, it became apparent that the phases of a plurality of light images output from the plurality of phase modulation areas 151 can be synchronized with each other and a predetermined interference effect can be caused in a hologram formed by overlapping the plurality of light images on one area. It became apparent that this effect of the first design method is more remarkable than that of the second design method.

### Second Example

The inventor performed other phase distribution design simulation by employing the first design method for the phase modulation layer 15 including four phase modulation areas 151 illustrated in FIG. 14. Part (a) of FIG. 33 illustrates a desired light image in an irradiation area (a far field) which was set when the phase distribution pattern A was designed. In part (a) of FIG. 33, the light intensity becomes larger as the color becomes lighter, and the light intensity becomes smaller as the color becomes darker. As illustrated in part (a) of FIG. 33, a goal of the phase distribution pattern A is to form a light image having a sinusoidal light intensity distribution in which a light intensity changes periodically in only one direction. Part (b) of FIG. 33 illustrates a distribution obtained by converting the light image illustrated in part (a) to the wave number space, that is, a target amplitude distribution in the wave number space. Part (c) of FIG. 33 is a diagram illustrating the phase distribution pattern A which was calculated on the basis of the target amplitude distribution illustrated in part (b). In part (c) of FIG. 33, the phase becomes closer to 2π (rad) as the color becomes lighter, and the phase becomes closer to 0 (rad) as the color becomes darker.

Part (a) of FIG. 34 illustrates a desired light image in an irradiation area (a far field) which was set when the phase distribution pattern B was designed. In part (a) of FIG. 34, the light intensity becomes larger as the color becomes lighter, and the light intensity becomes smaller as the color becomes darker. As illustrated in part (a) of FIG. 34, similarly to the phase distribution pattern A, a goal of the phase distribution pattern B was to form a light image having a sinusoidal light intensity distribution in which a light intensity changes periodically in only one direction. Here, the period of the sinusoidal wave was set to the same as the desired image when the phase distribution pattern A was designed, and the phase of the sinusoidal wave was shifted with respect to the desired light image when the phase distribution pattern A was designed. Part (b) of FIG. 34 illustrates a distribution obtained by converting the light image illustrated in part (a) to the wave number space, that is, a target amplitude distribution in the wave number space. Part (c) of FIG. 34 is a diagram illustrating a phase distribution pattern B which was calculated on the basis of the target amplitude distribution illustrated in part (b). In part (c) of FIG. 34, the phase becomes closer to 2π (rad) as the color becomes lighter, and the phase becomes closer to 0 (rad) as the color becomes darker.

Part (a) of FIG. 35 is a diagram illustrating an example in which the phase distribution pattern A was applied to two phase modulation areas 151 located on one diagonal and the phase distribution pattern B was applied to two phase modulation areas 151 located on the other diagonal. Part (b) of FIG. 35 is a diagram conceptually illustrating a difference between a light intensity in the two phase modulation areas 151 located on one diagonal and a light intensity in the two phase modulation areas 151 located on the other diagonal which is realized by individually controlling currents of the electrode parts 161. In part (b) of FIG. 35, the light intensity becomes larger as the color become lighter, and the light intensity becomes smaller as the color becomes darker.

FIG. 36 is a diagram illustrating a final light image which is supposed when a light image emitted from two phase modulation areas 151 having the phase distribution pattern A (see part (a) of FIG. 33) and a light image emitted from two phase modulation areas 151 having the phase distribution pattern B (see part (a) of FIG. 34) are caused to interfere with each other. When these light images are caused to interfere with each other, it is expected to obtain a sinusoidal light intensity distribution having a phase corresponding to a ratio of the light intensity of the light image emitted from the two phase modulation areas 151 having the phase distribution pattern B to the light intensity of the light image emitted from the two phase modulation areas 151 having the phase distribution pattern A.

FIGS. 37 and 38 are diagrams illustrating a final light image acquired through the simulation. FIG. 37 illustrates an example in which a phase difference between a light image emitted from a phase modulation area 151 having the phase distribution pattern A (see part (a) of FIG. 33) and a light image emitted from a phase modulation area 151 having the phase distribution pattern B (see part (a) of FIG. 34) is 45°. FIG. 38 illustrates an example in which the phase difference between the light images is 135°. When the light image emitted from the phase modulation areas 151 having the phase distribution pattern A is PA and the light image emitted from the phase modulation area 151 having the phase distribution pattern B is PB, the light intensity ratio is expressed as (PA/PB). In order to facilitate understanding of a change in phase with a change in the light intensity ratio, in FIGS. 37 and 38, final light images when the light intensity ratio (PA/PB) is 0/1.00, 0.25/0.75, 0.50/0.50, 0.75/0.25, and 1.00/0 are arranged in a direction crossing the changing direction of the light intensity.

As illustrated in the drawings, with the semiconductor light-emitting element according to the embodiment, it is possible to realize a sinusoidal light intensity distribution of which the phase can change dynamically by dynamically changing the light intensity ratio of light images emitted from a plurality of phase modulation areas 151 having different phase distribution patterns.

The semiconductor light-emitting element according to the present disclosure is not limited to the aforementioned embodiment and can be modified in various other forms. For example, in the embodiment, sinusoidal light images in which a period or phase differs between at least two light images LA are described as an example of the light images LA, but the light images LA are not limited thereto. With the semiconductor light-emitting element according to the present disclosure, it is possible to obtain a final light image by causing arbitrary light images LA to interfere with each other.

### REFERENCE SIGNS LIST

1, 1A, 1B . . . Semiconductor light-emitting element, 10 . . . Semiconductor substrate, 10a . . . Main surface, 10b . . . Rear surface, 11 . . . Clad layer, 12 . . . Active layer, 13 . . . Clad layer, 14 . . . Contact layer, 15, 15A . . . Phase modulation layer, 15a . . . Basic region, 15b . . . Different-refractive-index region, 15c . . . Cap region, 16 . . . Electrode (first electrode), 17 . . . Electrode (second electrode), 17a . . . Opening, 18 . . . Protection film, 19 . . . Antireflection film, 20 . . . Semiconductor stacked layer, 20a . . . First face, 20b . . . Second face, 21 . . . High-resistance region, 22 . . . Basic region, 24 . . . λ/4 plate, 31 . . . Drive circuit, 32 . . . Power supply circuit, 33 to 35 . . . line, 151 . . . Phase modulation area, 152 . . . Connection area, 152a . . . Opening, 152b, 152c . . . Part, 153 . . . Phase shift area, 161 . . . Electrode part, 201 . . . Initial value of amplitude distribution in wave number space, 202 . . . Initial value of phase distribution in wave number space, 203 . . . First function, 204 . . . Target amplitude distribution, 205 . . . Random phase distribution, 211 . . . Amplitude distribution in real space, 212 . . . Phase distribution in real space, 213 . . . Second function, 214 . . . Target amplitude distribution, 221 . . . Amplitude distribution in wave number space, 222 . . . Phase distribution in wave number space, 223 . . . Third function, 231 . . . Amplitude distribution in real space, 232 . . . Phase distribution in real space, 233 . . . Fourth function, D . . . Straight line, G . . . Centroid, L . . . Laser light, LA . . . Light image, O . . . Lattice point, P . . . Virtual plane, R . . . Unit constituent area

1: A semiconductor light-emitting element comprising:
a semiconductor stacked layer having a stacked structure including an active layer and a phase modulation layer between a first face and a second face, the phase modulation layer including a plurality of phase modulation areas which are arranged on a virtual plane perpendicular to a thickness direction of the phase modulation layer and which are optically coupled to each other, each of the plurality of phase modulation areas including a basic region with a first refractive index and a plurality of different-refractive-index regions which are provided in the basic region, the plurality of different-refractive-index regions having a second refractive index different from the first refractive index and being distributed in a two-dimensional shape along the virtual plane;
a first electrode opposite to the first face of the semiconductor stacked layer; and
a second electrode opposite to the second face of the semiconductor stacked layer,
wherein one or both of the first electrode and the second electrode include a plurality of electrode parts overlapping the plurality of phase modulation areas respectively when seen in a stacking direction of the semiconductor stacked layer, the plurality of electrode parts being electrically isolated from each other,
wherein light output from the active layer oscillates along the virtual plane in each of the plurality of phase modulation areas of the phase modulation layer and is applied from the plurality of phase modulation areas to a common irradiation area as light images according to arrangement of the plurality of different-refractive-index regions, and the common irradiation area is located in a direction crossing both of the first face and the second face of the semiconductor stacked layer, and
wherein the light images output from the plurality of phase modulation areas are synchronized in phase with each other.

2: The semiconductor light-emitting element according to claim 1, wherein a light intensity distribution of the light image output from each of the plurality of phase modulation areas includes a sinusoidal distribution in which a period or phase in at least one direction differs for each phase modulation area in at least two phase modulation areas of the plurality of phase modulation areas.

3: The semiconductor light-emitting element according to claim 1, wherein a light intensity distribution of the light image output from each of the plurality of phase modulation areas includes a sinusoidal distribution in which a period or phase in two directions perpendicular to each other differs for each phase modulation area in at least two phase modulation areas of the plurality of phase modulation areas.

4: The semiconductor light-emitting element according to claim 1, wherein, when a virtual tetragonal lattice along the virtual plane is set and a straight line passing through a corresponding lattice point and being oblique by same angle with respect to the tetragonal lattice is set for each of a plurality of lattice points of the tetragonal lattice, a centroid of each of the plurality of different-refractive-index regions is disposed on corresponding straight line in each of the plurality of phase modulation areas, and a distance between the centroid of each of the plurality of different-refractive-index regions and the corresponding lattice point of each of the plurality of different-refractive-index regions is individually set according to a predetermined light image as the light image.

5: The semiconductor light-emitting element according to claim 4, wherein the phase modulation layer further includes a connection area located between neighboring phase modulation areas out of the plurality of phase modulation areas,
wherein the connection area includes a basic region with the first refractive index and a plurality of different-refractive-index regions with the second refractive index, and
wherein centroids of the plurality of different-refractive-index regions of the connection area are located at the lattice points of the tetragonal lattice.

6: The semiconductor light-emitting element according to claim 5, wherein a planar shape of the connection area when seen in a stacking direction of the semiconductor stacked layer is a lattice shape.

7: The semiconductor light-emitting element according to claim 4, wherein areas of the plurality of different-refractive-index regions on a section perpendicular to a thickness direction of the phase modulation layer are individually set according to a predetermined light image as the light image.

8: The semiconductor light-emitting element according to claim 4, wherein tetragonal lattices of neighboring phase modulation areas out of the plurality of phase modulation areas are offset from each other.

9: The semiconductor light-emitting element according to claim 4, further comprising a π/4 plate provided to face a light emission surface of the semiconductor light-emitting element,
wherein tetragonal lattices of neighboring phase modulation areas out of the plurality of phase modulation areas are offset from each other by n·a+a/2 (where a is a lattice spacing, and n is an integer equal to or greater than 0).

10: The semiconductor light-emitting element according to claim 1, wherein the first electrode includes the plurality of electrode parts,
wherein the stacked structure further includes a clad layer provided between a layer group including the phase modulation layer and the active layer and the first face, and
wherein the clad layer includes a high-resistance region located between neighboring phase modulation areas out of the plurality of phase modulation areas when seen in a stacking direction of the semiconductor stacked layer.

11: The semiconductor light-emitting element according to claim 10, wherein the phase modulation layer is provided between the clad layer and the active layer, and
wherein the high-resistance region extends from a boundary of the clad layer on the first face side to the phase modulation layer.

12: The semiconductor light-emitting element according to claim 10, wherein a planar shape of the high-resistance region when seen in the stacking direction of the semiconductor stacked layer is a lattice shape.

13: The semiconductor light-emitting element according to claim 1, further comprising a semiconductor substrate including a main surface and a rear surface,
wherein the semiconductor stacked layer is provided on the main surface of the semiconductor substrate, and the second face of the semiconductor stacked layer is opposite to the main surface of the semiconductor substrate,
wherein the first electrode is provided on the first face and includes the plurality of electrode parts, and
wherein the second electrode is provided on the rear surface of the semiconductor substrate.
